(19) United States
(12) Patent Application Publication
(10) Pub. No.: US 2015/0014659 A1
(43) Pub. Date: Jan. 15, 2015

(54) IRIDIUM COMPLEX AND ORGANIC LIGHT-EMITTING DEVICE INCLUDING THE SAME

(71) Applicants: SAMSUNG DISPLAY CO., LTD., Yongin-City (KR); Pusan National University Industry-University Cooperation Foundation, Busan (KR)

(72) Inventors: Soung-Wook KIM, Yongin-City (KR); Jae-Hong KIM, Yongin-City (KR); Myeong-Suk KIM, Yongin-City (KR); Moon-Jae LEE, Yongin-City (KR); Young-Inn KIM, Yongin-City (KR)

(73) Assignees: SAMSUNG DISPLAY CO., LTD., Yongin-City (KR); Pusan National University Industry-University Cooperation Foundation, Busan (KR)

(21) Appl. No.: 14/288,937

(22) Filed: May 28, 2014

(30) Foreign Application Priority Data
Jul. 11, 2013 (KR) 10-2013-0081787

(51) Int. Cl. H01L 51/00; H01L 27/32; H01L 51/52

(52) U.S. Cl. CPC H01L 51/0085; H01L 51/52; H01L 27/3244; H01L 51/5012
USPC 257/40; 546/4

(57) ABSTRACT

An organic light-emitting device including an iridium complex represented by Formula 1:

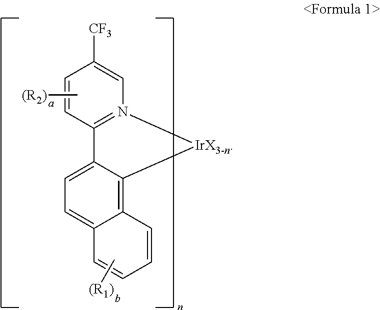

### CROSS-REFERENCE TO RELATED APPLICATION

The present application claims priority under 35 U.S.C. §119 to Korean Patent Application No. 10-2013-0081787, filed on Jul. 11, 2013, in the Korean Intellectual Property Office, and entitled: “Iridium Complex and Organic Light-Emitting Device Including The Same,” which is incorporated by reference herein in its entirety.

### BACKGROUND

1. Field

Provided is an iridium complex and an organic light-emitting device including the same.

2. Description of the Related Art

Organic light-emitting devices (OLEDs) are self-emitting devices that may have wide viewing angles, excellent contrast, quick response times, and excellent luminance, driving voltage, and response speed characteristics, and can provide multicolored images.

### SUMMARY

Embodiments are directed to an iridium complex represented by Formula 1:

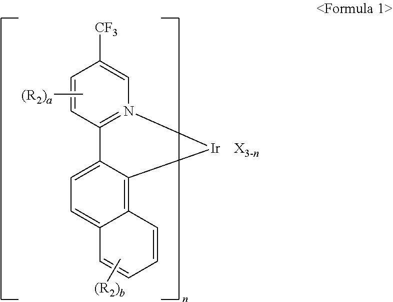

wherein:

R₁ and R₂ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₂-C₃₀ heteroaryl group;

X is a bidendate ligand having −1 valence;

a is an integer of 1 to 3;

b is an integer of 1 to 6; and

n is 2 or 3;

provided that if a is 2 or greater, a plurality of R₂'s are optionally connected to each other to form a ring.

R₁ and R₂ may each independently be selected from:

i) a C₆-C₁₄ aryl group and a C₂-C₁₄ heteroaryl group; and

ii) a C₆-C₁₄ aryl group and a C₂-C₁₄ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₁₄ aryl group, and C₂-C₁₄ heteroaryl group.

R₁ and R₂ may each independently be selected from:

i) a phenyl group, a biphenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group; and

ii) a phenyl group, a biphenyl group, a naphthyl group, an anthryl group, a pyrenyl group, a phenanthrenyl group, a fluorenyl group, a pyridinyl group, a bipyridinyl group, a terpyridinyl group, a pyrazinyl group, a pyrimidinyl group, a triazinyl group, a quinolinyl group, an isoquinolinyl group, a quinoxalinyl group, a phenanthrolinyl group, and a carbazole group, each substituted with at least one of a deuterium atom, a fluorine (F), a chlorine (Cl), a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group.

R₁ and R₂ may each independently be selected from a hydrogen atom, a deuterium atom, —CF₃, and Formula 2a:

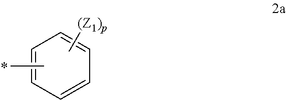

wherein in Formula 2a:

Z₁ is a hydrogen atom, a deuterium atom, a substituted or unsubstituted C₁-C₂₀ alkyl group, a substituted or unsubstituted C₅-C₂₀ aryl group, a substituted or unsubstituted C₃-C₂₀ heteroaryl group, a substituted or unsubstituted C₆-C₂₀ condensed polycyclic group, an amino group substituted with a C₅-C₂₀ aryl group or a C₃-C₂₀ heteroaryl group, a halogen atom, a cyano group, a nitro group, a hydroxyl group, or a carboxyl group;

p is an integer of 1 to 5; and

* indicates a binding site.

The iridium complex of Formula 1 may be represented by Formula 2:

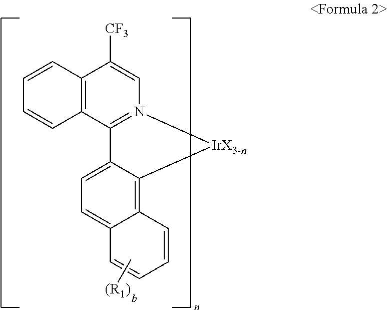

wherein, in Formula 2, substituents and symbols are each defined as described above with reference to Formula 1.

In an embodiment, n may be 2 and X may be acetylacetonate, hexafluoroacetonate, tetramethylheptadionate, dibenzoylmethane, picolinate, salicylanilide, 8-hydroxyquinolate, or 1,5-dimethyl-3-pyrazole carboxylate.

In an embodiment, n may be 2 and X may be represented by Formula 3a or Formula 3b:

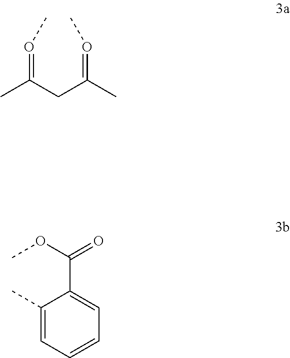

wherein, in Formulae 3a and 3b, a part shown in dotted lines indicates a binding with the iridium molecule.

The compound of Formula 1 may be one of Compounds 1 to 18:

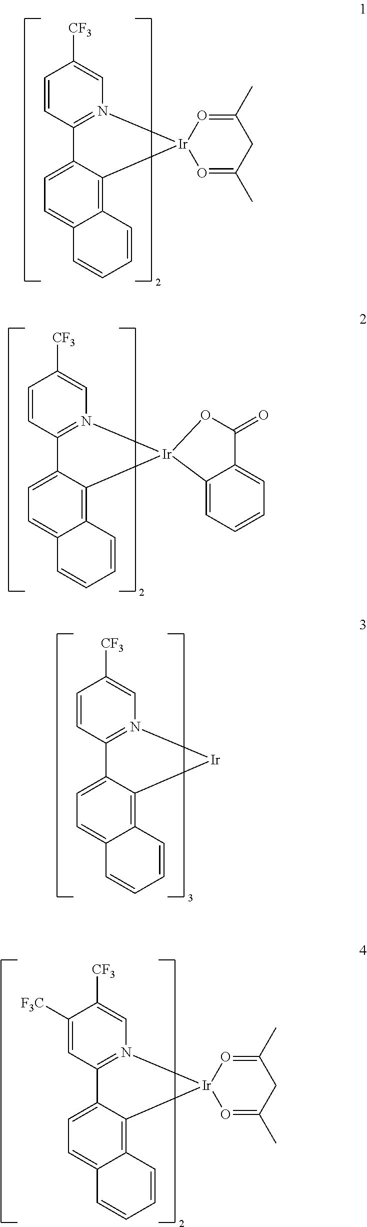

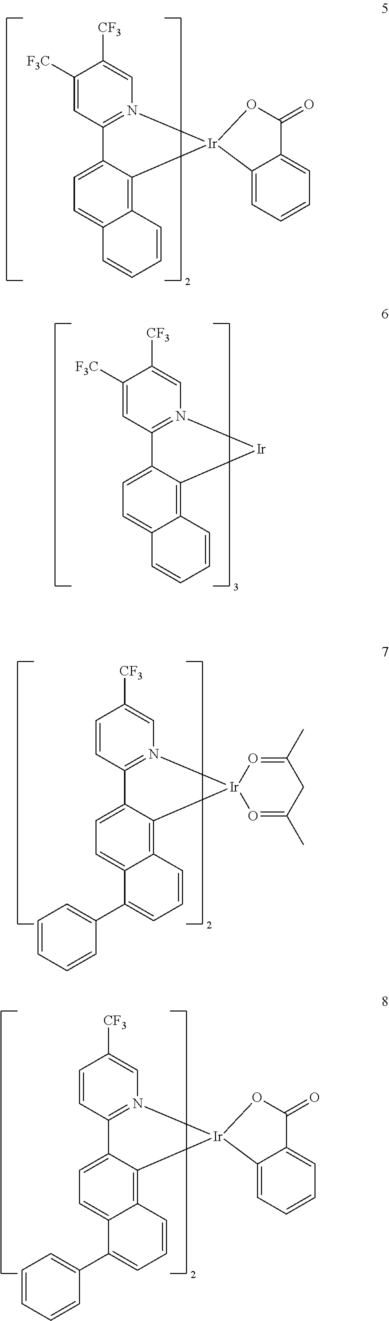

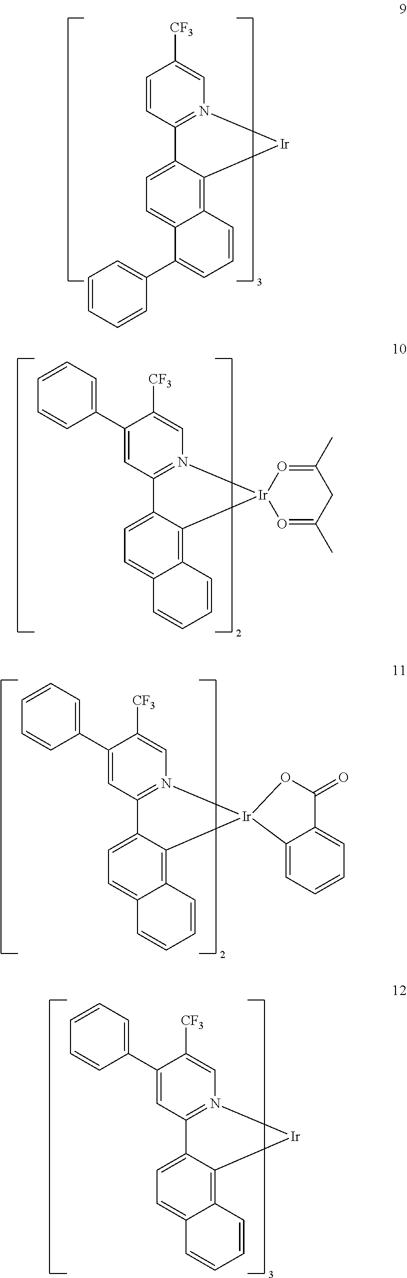

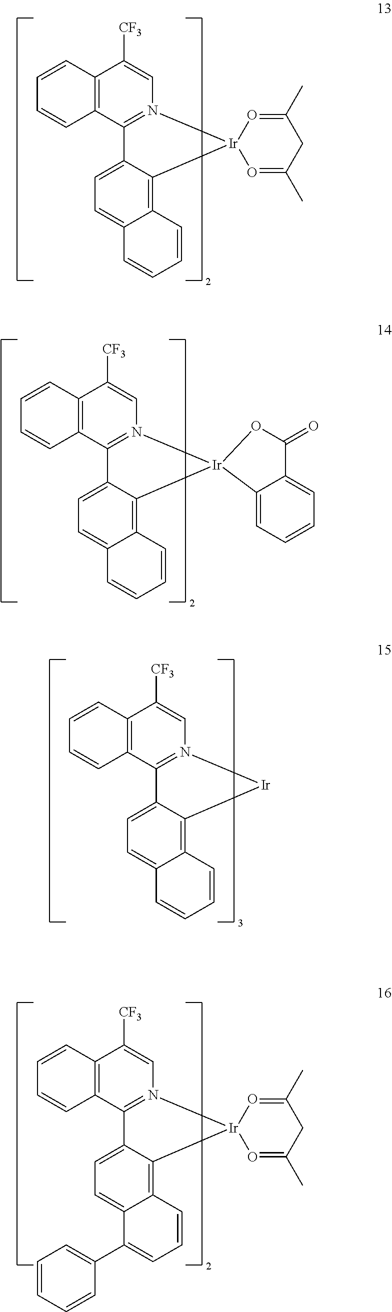

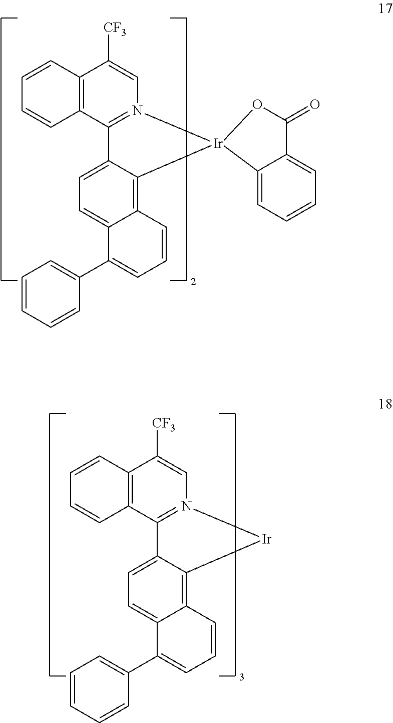

Also provided is an organic light-emitting device, including a first electrode; a second electrode; and an organic layer disposed between the first electrode and the second electrode. The organic layer may include the presently disclosed iridium complex.

The organic layer may be an emission layer.

The organic layer may be a red phosphorescent emission layer, and the iridium complex may be a phosphorescent dopant.

The organic layer may include an emission layer, and, optionally, one or more of a hole injection layer, a hole transport layer, a functional layer having both hole injection and hole transport capabilities at the same time, an electron injection layer, an electron transport layer, or a functional layer having both electron injection and electron transport capabilities at the same time. The emission layer may include the presently disclosed iridium complex. The emission layer may further include an anthracene-based compound, an arylamine-based compound, or a styryl-based compound.

The organic layer may include an emission layer, and, optionally, one or more of a hole injection layer, a hole transport layer, or a functional layer having both hole injection and hole transport capabilities at the same time. A red emission layer of the emission layer may include the presently disclosed iridium complex. The emission layer may further include at least one layer selected from a green emission layer, a blue emission layer, and a white emission layer of the emission layer that includes a phosphorescent compound.

The hole injection layer, the hole transport layer, or the functional layer may having both hole injection and hole transport capabilities at the same time may include a charge-generating material.

The charge-generating material may be a p-dopant.

The p-dopant may be a quinone derivative, a metal oxide, or a cyano group-containing compound.

The organic layer may include an emission layer, and, optionally, one or more of an electron injection layer, an electron transport layer, or a functional layer having both electron injection and electron transport capabilities at the same time. The emission layer may include the presently disclosed iridium. The electron injection layer, the electron transport layer, or the functional layer having both electron injection and electron transport capabilities at the same time may include an electron-transporting organic compound and a metal complex.

The metal complex may be lithium quinolate (LiQ) or Compound 203:

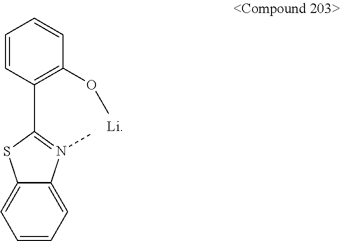

The organic layer may be formed using a wet process.

Further provided is a flat panel display device, including the presently disclosed organic light-emitting device. The first electrode of the organic light-emitting device may be electrically connected to a source electrode or a drain electrode of a thin film transistor (TFT).

### BRIEF DESCRIPTION OF THE DRAWING

Features will become apparent to those of skill in the art by describing in detail exemplary embodiments with reference to the attached drawings in which:

FIG. 1 illustrates a graph showing an ultraviolet (UV) absorption spectrum of Complex 1 according to Example 1 in solution, according to an embodiment;

FIG. 2 illustrates a graph showing a photoluminescence (PL) spectrum of Complex 1 according to Example 1, according to an embodiment;

FIG. 3 illustrates a graph showing cyclic voltammetry (CV) data of Complexes 1 and 2 according to Examples 1 and 2, according to an embodiment; and

FIG. 4 illustrates a schematic view of a structure of an organic light-emitting device (OLED), according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration.

According to an embodiment, an iridium (Ir) complex is represented by Formula 1 below:

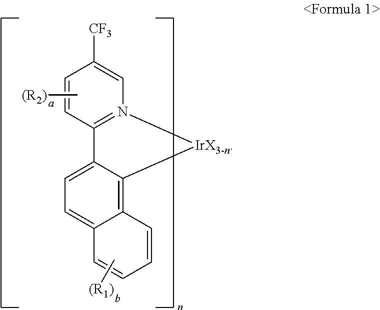

In Formula 1, R₁ and R₂ of main ligands may each independently be selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₂-C₃₀ heteroaryl group;

an auxiliary ligand X is a bidendate ligand having −1 valence;

a may be an integer of 1 to 3;

b may be an integer of 1 to 6; and

n may be 2 or 3;

provided that if a is 2 or greater, a plurality of R₂'s are optionally connected to each other to form a ring.

In Formula 1, a main ligand may bind to a central Ir metal by a naphthyl group of the main ligand (see the part shown in a dotted circle in the Formula below), in which the binding occurs under steric hindrance with the central Ir metal to some extent. In this regard, it is understood that a compound according to an embodiment may have better characteristics than a complex having no such steric hindrance among the main ligand and the central Ir metal (see results of Comparative Examples 1 and 2 described later). The steric hindrance may affect properties of a compound according to an embodiment in terms of light-emitting characteristics or efficiency.

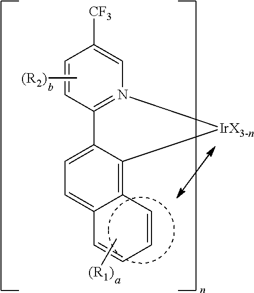

According to another embodiment, R₁ and R₂ may each be independently selected from:

i) a C₆-C₁₄ aryl group and a C₂-C₁₄ heteroaryl group; and

ii) a C₆-C₁₄ aryl group and a C₂-C₁₄ heteroaryl group, each selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₁₄ aryl group, and C₂-C₁₄ heteroaryl group.

According to another embodiment, R₁ and R₂ may each independently be selected from:

i) a phenyl group, a biphenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group; and

ii) a phenyl group, a biphenyl group, a naphthyl group, an anthryl group, a pyrenyl group, a phenanthrenyl group, a fluorenyl group, a pyridinyl group, a bipyridinyl group, a terpyridinyl group, a pyrazinyl group, a pyrimidinyl group, a triazinyl group, a quinolinyl group, an isoquinolinyl group, a quinoxalinyl group, a phenanthrolinyl group, and a carbazole group, each substituted with at least one of a deuterium atom, a fluorine (F), a chlorine (Cl), a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group.

According to another embodiment, R₁ and R₂ may each independently be selected from a hydrogen atom, a deuterium atom, —CF₃, and a compound represented by Formula 2a below:

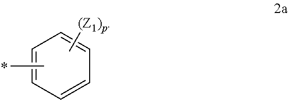

In Formula 2a, Z₁ may be a hydrogen atom, a deuterium atom, a substituted or unsubstituted C₁-C₂₀ alkyl group, a substituted or unsubstituted C₅-C₂₀ aryl group, a substituted or unsubstituted C₃-C₂₀ heteroaryl group, a substituted or unsubstituted C₆-C₂₀ condensed polycyclic group, an amino group substituted with a C₅-C₂₀ aryl group or a C₃-C₂₀ heteroaryl group, a halogen atom, a cyano group, a nitro group, a hydroxyl group, or a carboxyl group;

p may be an integer of 1 to 5; and

* indicates a binding site.

According to another embodiment, the compound of Formula 1 may be represented by Formula 2 below:

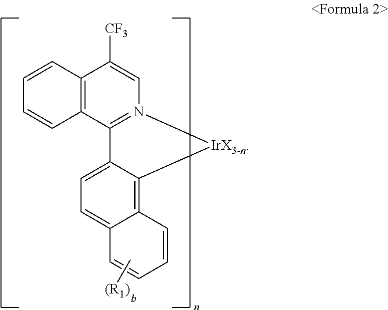

The compound of Formula 2 above is an embodiment of forming a ring by connecting the plurality of R₂'s of Formula 1. Detailed descriptions of substituents and symbols in Formula 2 are each defined as described above.

According to another embodiment, X may be acetylacetonate, hexafluoroacetonate, tetramethylheptadionate, dibenzoylmethane, picolinate, salicylanilide, 8-hydroxyquinolate, or 1,5-dimethyl-3-pyrazole carboxylate.

According to another embodiment, X may be a compound represented by one of Formulae 3a and 3b below:

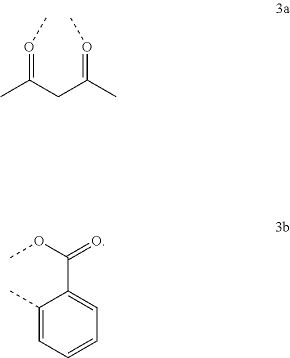

In Formulae 3a and 3b, a part shown in dotted lines indicates a binding with the iridium molecule.

Hereinafter, the definition of representative substituent used herein will now be described in detail. (In this regard, numbers of carbons limiting a substituent are non-limited, and thus the substituent characteristics are not limited. The substituents not defined herein are defined as substituents generally known to one of ordinary skill in the art).

The unsubstituted C₁-C₆₀ alkyl group used herein may be linear or branched. Non-limiting examples of the unsubstituted C₁-C₆₀ alkyl group are a methyl group, an ethyl group, a propyl group, an iso-butyl group, a sec-butyl group, a pentyl group, an iso-amyl group, a hexyl group, a heptyl group, an octyl group, a nonanyl group, and a dodecyl group. At least one hydrogen atom of the unsubstituted C₁-C₆₀ alkyl group may be substituted with a deuterium atom, a halogen atom, a hydroxyl group, a nitro group, a cyano group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₂-C₁₆ heteroaryl group.

The unsubstituted C₂-C₆₀ alkenyl group used herein refers to an unsubstituted alkyl group having one or more carbon-carbon double bonds in the center or at a terminal thereof. Examples of the unsubstituted C₂-C₆₀ alkenyl group are an an ethynyl group, a propenyl group, and a butenyl group. At least one hydrogen atom of the unsubstituted alkenyl group may be substituted with the same substituent as described above in conjunction with the substituted C₁-C₆₀ alkyl group.

The unsubstituted C₂-C₆₀ alkynyl group used herein refers to an unsubstituted alkyl group having one or more carbon-carbon triple bonds in the center or at a terminal thereof. Examples of the unsubstituted C₂-C₆₀ alkynyl group are an acetylene group, a propylene group, a phenylacetylene group, a naphthylacetylene group, an isopropylacetylene group, a t-butylacetylene group, and a diphenylacetylene group. At least one hydrogen atom of the unsubstituted C₂-C₆₀ alkynyl group may be substituted with the same substituent as described above in conjunction with the substituted C₁-C₆₀ alkyl group.

The unsubstituted C₃-C₆₀ cycloalkyl group used herein refers to an alkyl group in the form of C₃-C₆₀ rings, and at least one hydrogen atom of the C₃-C₆₀ cycloalkyl group may be substituted with the same substituent as described above in conjunction with the substituted C₁-C₆₀ alkyl group.

The unsubstituted C₁-C₆₀ alkoxy group used herein has a structure of —OA (wherein, A is an unsubstituted C₁-C₆₀ alkyl group described above). Non-limiting examples of the unsubstituted C₁-C₆₀ alkoxy group are a methoxy group, an ethoxy group, a propoxy group, an isopropyloxy group, a butoxy group, and a pentoxy group. At least one hydrogen atom of the unsubstituted alkoxy group may be substituted with the same substituent as described above in conjunction with the substituted C₁-C₆₀ alkyl group.

The unsubstituted C₆-C₆₀ aryl group used herein refers to a carbocyclic aromatic system including at least one ring. When unsubstituted C₆-C₆₀ aryl group has two or more rings, the rings may be fused or linked to each other by a single bond. The term ‘aryl’ refers to an aromatic system, such as phenyl, napthyl, and anthracenyl. Also, at least one hydrogen atom of the unsubstituted C₆-C₆₀ aryl group may be substituted with the same substituent as described above in conjunction with the substituted C₁-C₆₀ alkyl group.

Examples of the substituted or unsubstituted C₆-C₆₀ aryl group are a phenyl group, a C₁-C₁₀ alkylphenyl group (i.e., an ethylphenyl group), a biphenyl group, a C₁-C₁₀ alkylbiphenyl group, a C₁-C₁₀ alkoxybiphenyl group, an o-, m-, and p-toryl group, an o-, m-, and p-cumenyl group, a mesityl group, a phenoxyphenyl group, an (α,α-dimethylbenzene)phenyl group, an (N,N′-dimethy)aminophenyl group, an (N,N′-diphenyl)aminophenyl group, a pentalenyl group, an indenyl group, a naphtyl group, a C₁-C₁₀ alkylnaphtyl group (i.e., a methylnaphtyl group), a C₁-C₁₀ alkoxynaphtyl group (i.e., a methoxynaphtyl group), an anthracenyl group, an azulenyl group, a heptalenyl group, an acenaphtylenyl group, a phenalenyl group, a fluorenyl group, an anthraquinolyl group, a methylanthryl group, a phenanthryl group, a triphenylene group, a pyrenyl group, a chrycenyl group, an ethyl-chrysenyl group, a picenyl group, a perylenyl group, a pentaphenyl group, a pentacenyl group, a tetraphenylenyl group, a hexaphenyl group, a hexacenyl group, a rubicenyl group, a coronelyl group, a trinaphtylenyl group, a heptaphenyl group, a heptacenyl group, a pyranthrenyl group, and an ovalenyl group.

The unsubstituted C₂-C₆₀ heteroaryl group used herein may include 1, 2, 3, or 4 heteroatoms selected from N, O, P, or S. When the unsubstituted C₂-C₆₀ heteroaryl group has two or more rings, the rings are fused or linked to each other by a single bond. Examples of the unsubstituted C₂-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazol group, an indolyl group, a quinolinyl group, an isoquinolinyl group, and a dibenzothiophene group. Also, at least one hydrogen atom of the unsubstituted C₂-C₆₀ heteroaryl group may be substituted with the same substituent as described above in conjunction with the substituted C₁-C₆₀ alkyl group.

The unsubstituted C₆-C₆₀ aryloxy group used herein may be a group represented by —OA₁ in which A₁ is a C₆-C₆₀ aryl group. An example of the unsubstituted C₆-C₆₀ aryloxy group is a phenoxy group. At least one hydrogen atom of the unsubstituted C₆-C₆₀ aryloxy group may be substituted with the same substituent as described above in conjunction with the substituted C₁-C₆₀ alkyl group.

The unsubstituted C₆-C₆₀ arylthio group used herein may be a group represented by —SA₁ in which A₁ is a C₆-C₆₀ aryl group. Examples of the unsubstituted C₆-C₆₀ arylthio group are a benzenethio group and a naphthylthio group. At least one hydrogen atom of the unsubstituted C₆-C₆₀ arylthio group may be substituted with the same substituent as described above in conjunction with the substituted C₁-C₆₀ alkyl group

The unsubstituted C₆-C₆₀ condensed polycyclic group used herein refers to a substituent including at least two rings, in which at least one aromatic ring and/or at least one non-aromatic ring are fused to each other, or refers to a substituent having an unsaturated group within a ring but being unable to form a conjugated structure. Therefore, the unsubstituted C₆-C₆₀ condensed polycyclic group is distinct from the aryl group or the heteroaryl group in terms of being non-aromatic.

Examples of the iridium complex of Formula 1 are the following compounds:

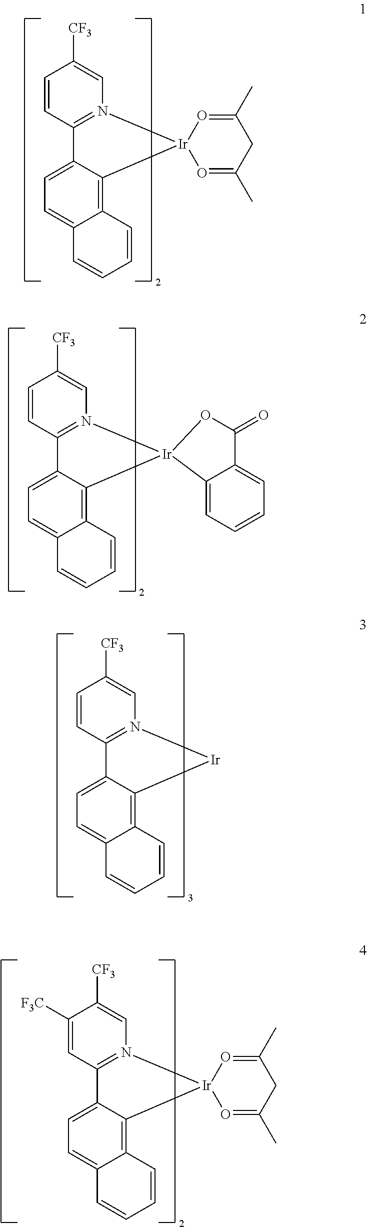

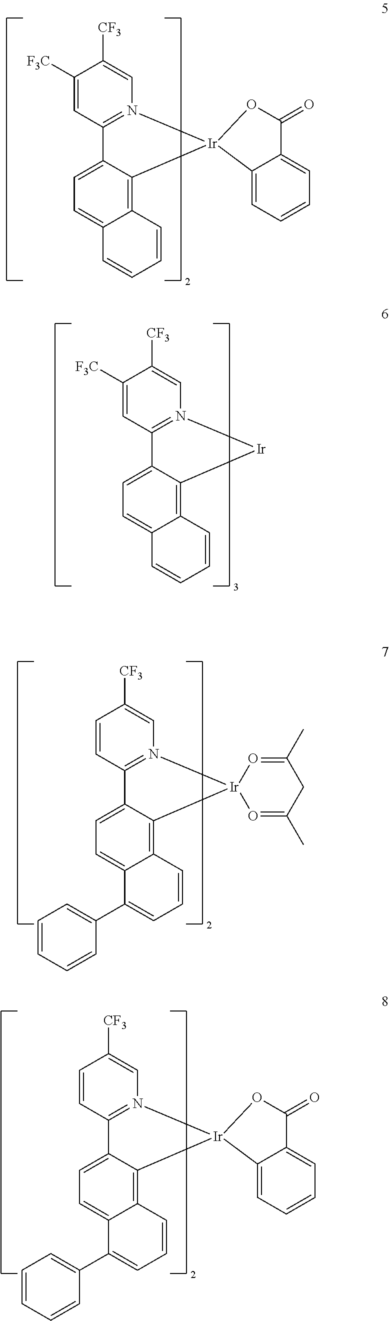

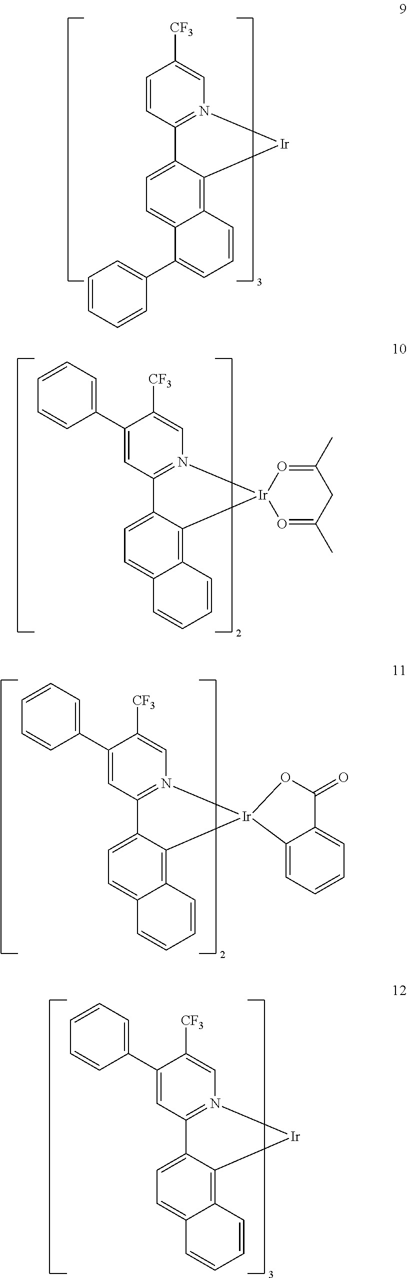

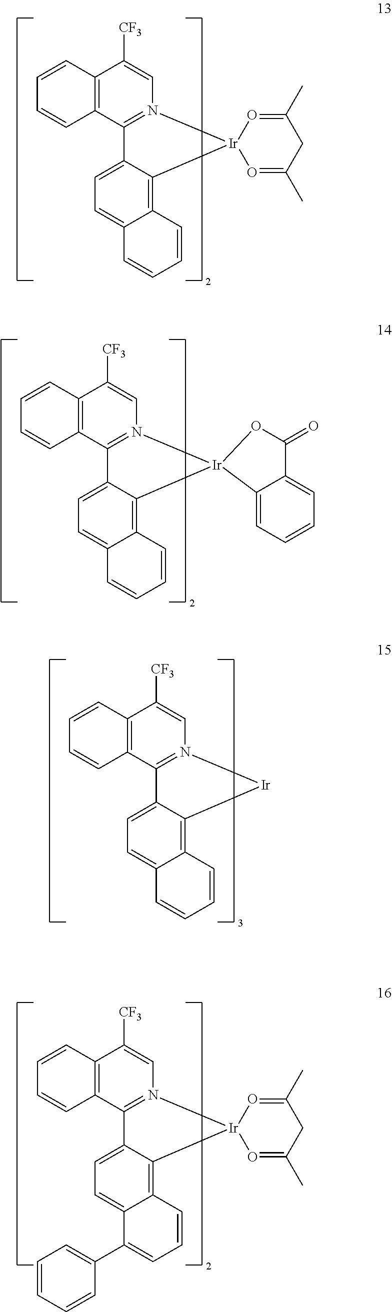

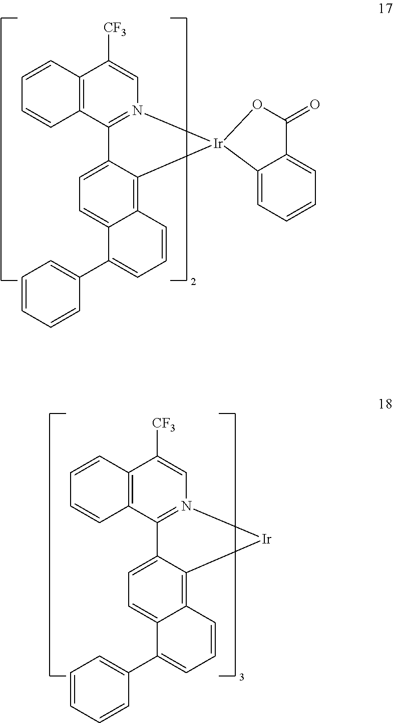

One or more of the iridium complexes of Formula 1 may be used between a pair of electrodes included in the OLED. For example, one or more of the iridium complexes of Formula 1 may be used in an emission layer.

Therefore, according to another embodiment, an OLED includes a first electrode; a second electrode; and an organic layer disposed between the first electrode and the second electrode and including an iridium complex represented by Formula 1 above.

The expression “(the organic layer) includes at least one iridium complex” used herein may be interpreted as an expression “(the organic layer) includes one type of the iridium complex of Formula 1 or two or more different types of the iridium complex of Formula 1”.

For example, the organic layer may include only Complex 1 according to Example 1, described below, as the iridium complex. Complex 1 according to Example 1 may be included in an emission layer of the OLED. Alternatively, the organic layer may include Complexes 1 and 2 according to Examples 1 and 2, described below, as the iridium complex. Both Complexes 1 and 2 according to Examples 1 and 2 may be included in the same layer (i.e., an emission layer).

The organic layer may further include at least one of a hole injection layer (HIL), a hole transport layer (HTL), a functional layer having both hole injection and hole transport capabilities (hereinafter, referred to as a “H-functional layer)”, a buffer layer, and an electron blocking layer (EBL), between the first electrode and the emission layer. Also, the organic layer may further include at least one of an electron blocking layer (EBL), an electron transport layer (ETL), and an electron injection layer (EIL), between the second electrode and the emission layer (EML).

The term “organic layer” used herein refers to a single-layer and/or a multi-layer disposed between the first electrode and the second electrode of the OLED.

The organic layer may include an EML, and the EML may include at least one iridium complex.

The iridium complex according to an embodiment included in the EML may act as a dopant, and the EML may further include a host. Examples of the host will be described later.

As described above, the OLED including the iridium complex according to an embodiment may emit red light, for example, red phosphorescent light.

FIG. 4 illustrates a schematic view of a structure of an OLED, according to an embodiment. Hereinafter, a structure and a manufacturing method of an OLED according to an embodiment will be described in detail with reference to FIG. 4.

The substrate (not illustrated) may be any substrate used in an OLED, such as a glass substrate or a transparent plastic substrate with excellent mechanical strength, thermal stability, transparency, surface smoothness, ease of handling, and water resistance.

The first electrode may be formed on the substrate by depositing or sputtering a first electrode-forming material. When the first electrode is an anode, a material having a high work function may be used as the first electrode-forming material to facilitate hole injection. The first electrode may be a reflective electrode or a transmission electrode. The first electrode-forming material may be transparent and have excellent conductivity, and examples thereof are indium tin oxide (ITO), indium zinc oxide (IZO), tin oxide (SnO₂), and zinc oxide (ZnO). When magnesium (Mg), aluminum (Al), aluminum-lithium (Al—Li), calcium (Ca), magnesium-indium (Mg—In), or magnesium-silver (Mg—Ag) are used, the first electrode may be formed as a reflective electrode.

The first electrode may have a single-layer structure or a multi-layer structure including at least two layers. For example, the first electrode may have a three-layer structure of ITO/Ag/ITO.

The organic layer may be disposed on the first electrode.

The organic layer may include an HIL, an HTL, a buffer layer, and EML, an ETL, and an EIL.

An HIL may be formed on the first electrode by using various methods, such as vacuum deposition, spin coating, casting, and Langmuir-Blodgett (LB) deposition.

When the HIL is formed by vacuum deposition, deposition conditions may vary depending on a compound that is used to form the HIL, and the desired structure and thermal properties of the HIL to be formed. For example, the conditions may be selected from a temperature in a range from about 100° C. to about 500° C., a pressure in a range from about 10⁻⁸ torr to about 10⁻³ torr, and a deposition rate in a range from about 0.01 Å/sec to about 100 Å/sec.

When the HIL is formed by spin coating, coating conditions may vary depending on a compound that is used to form the HIL, and the desired structure and thermal properties of the HIL to be formed. For example, the conditions may be selected from a coating rate in a range from about 2,000 rpm to about 5,000 rpm, and a temperature in a range from about 80° C. to about 200° C. at which heat treatment is performed to remove a solvent after coating.

The HIL may be formed of a hole-injecting material. Examples thereof include N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA, N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), and polyaniline/poly(4-styrenesulfonate) (PANI/PSS):

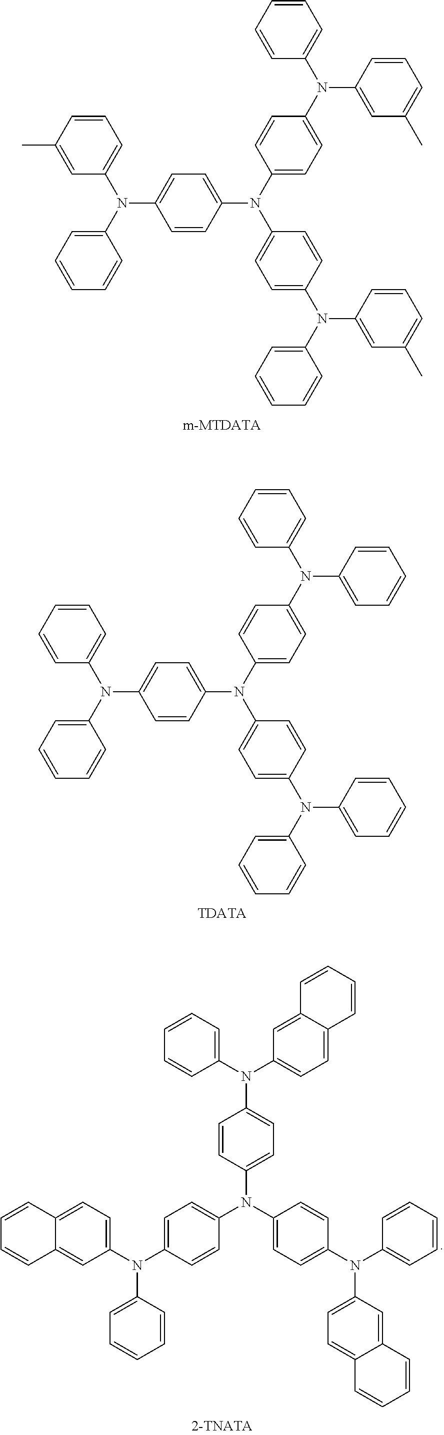

A thickness of the HIL may be in a range from about 100 Å to about 10,000 Å, for example, about 100 Å to about 1,000 Å. Maintaining the thickness of the HIL within the above ranges may help provide the HIL with satisfactory hole-injecting ability without a substantial increase in a driving voltage.

Then, the HTL may be formed on the HIL by using various methods, such as vacuum deposition, spin coating, casting, and LB deposition. When the HTL is formed by vacuum deposition and spin coating, deposition and coating conditions may be similar to those for the formation of the HIL, although the conditions may vary depending on a compound that is used to form the HIL.

The HTL may be formed of a hole-transporting material. Examples thereof include a carbazole derivative, such as N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB):

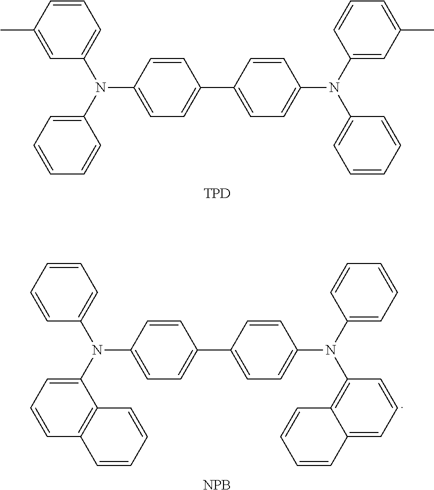

A thickness of the HTL may be in a range from about 50 Å to about 2,000 Å, for example, about 100 Å to about 1,500 Å. Maintaining the thickness of the HTL within the above ranges may help provide the HTL with satisfactory hole-transporting ability without a substantial increase in a driving voltage.

The H-functional layer (a functional layer having both hole injection and hole transport capabilities) may include one or more materials selected from the above-described materials for the HIL and the HTL. A thickness of the H-functional layer may be in a range from about 500 Å to about 10,000 Å, for example, about 100 Å to about 1,000 Å. Maintaining the thickness of the H-functional within the above ranges may help provide the HTL with satisfactory hole-injecting and hole-transporting abilities without a substantial increase in driving voltage.

In some embodiments, at least one of the HIL, the HTL, and the H-functional layer may include at least one of the compounds represented by Formulae 300 and 350 below:

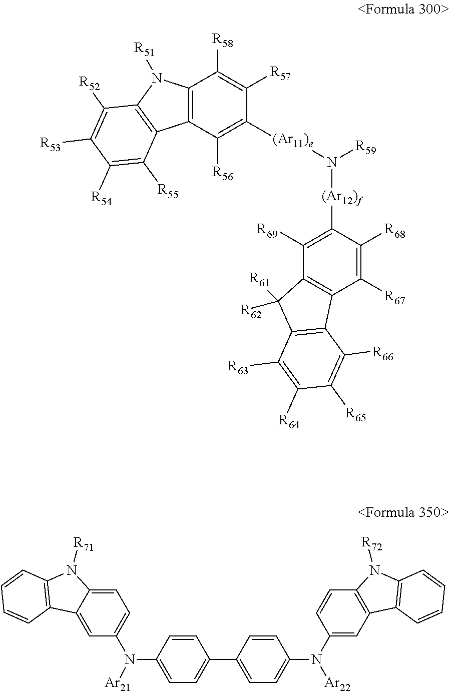

In Formula 300, Ar₁₁ and Ar₁₂ may each independently be a substituted or unsubstituted C₆-C₆₀ arylene group. For example, Ar₁₁ and Ar₁₂ may each independently be a substituted or unsubstituted phenylene group, a substituted or unsubstituted naphthylene group, a substituted or unsubstituted fluorenylene group, or a substituted or unsubstituted anthrylene group. At least one substituent of the substituted phenylene group, the substituted naphthylene group, the substituted fluorenylene group, and the substituted anthrylene group may be a deuterium atom, a halogen atom, a hydroxyl group, a cyano group, a C₁-C₂₀ alkyl group, a C₁-C₂₀ alkoxy group, a phenyl group, a naphthyl group, an anthryl group, a carbazole group, or a carbazole group substituted with a phenyl group.

In Formula 350, Ar₂₁ and Ar₂₂ may independently be a substituted or unsubstituted C₆-C₆₀ aryl group or a substituted or unsubstituted C₂-C₆₀ heteroaryl group. For example, Ar₂₁ and Ar₂₂ may each independently be a substituted or unsubstituted phenyl group, a substituted or unsubstituted naphthyl group, a substituted or unsubstituted phenanthrenylene group, a substituted or unsubstituted anthryl group, a substituted or unsubstituted pyrenyl group, a substituted or unsubstituted chrysenylenylene group, a substituted or unsubstituted fluorenyl group, a substituted or unsubstituted carbazole group, a substituted or unsubstituted dibenzofuranyl group, or a substituted or unsubstituted dibenzothiophenyl group. At least one substituent of the substituted phenyl group, the substituted naphthyl group, the substituted phenanthrenyl group, the substituted anthryl group, the substituted pyrenyl group, the substituted chrysenylenylene group, the substituted fluorenyl group, the substituted carbazole group, the substituted dibenzofuranyl group, and the substituted dibenzothiophenyl group may be selected from

a deuterium atom; a halogen atom; a hydroxyl group; a cyano group; a nitro group; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group; a C₁-C₁₀ alkoxy group; a phenyl group, a naphthyl group, a fluorenyl group, a phenanthrenyl group, an anthryl group, a triphenylrenyl group, a pyrenyl group, a chrysenylenylene group, an imidazolyl group, an imidazolinyl group, an imidazopyridinyl group, an imidazopyrimidinyl group, a pyridinyl group, a pyrazinyl group, a pyrimidinyl group, and an indolyl group; and

a phenyl group, a naphthyl group, a fluorenyl group, a phenanthrenyl group, an anthryl group, a triphenylrenyl group, a pyrenyl group, a chrysenylenylene group, an imidazolyl group, an imidazolinyl group, an imidazopyridinyl group, an imidazopyrimidinyl group, a pyridinyl group, a pyrazinyl group, a pyrimidinyl group, and an indolyl group, each substituted with at least one of a deuterium atom a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 300, e and f may each independently be an integer of 0 to 5. For example, e may be 1 and f may be 0.

In Formulae 300 and 350, R₅₁ to R₅₈, R₆₁ to R₆₉, R₇₁, and R₇₂ may each independently be a hydrogen atom, a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₆-C₆₀ aryl group, a substituted or unsubstituted C₆-C₆₀ aryloxy group, or a substituted or unsubstituted C₆-C₆₀ arylthio group.

In some embodiments, R₅₁ to R₅₈, R₆₁ to R₆₉, R₇₁, and R₇₂ may be each independently at least one of a hydrogen atom; a deuterium atom; a halogen atom; a hydroxyl group; a cyano group; —NO₂; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (i.e., a methyl group, an ethyl group, a propyl group, a butyl group, a pentyl group, and a hexyl group); a C₁-C₁₀ alkoxy group (i.e., a methoxy group, an ethoxy group, a propoxy group, a butoxy group, and a pentoxy group); a C₁-C₁₀ alkyl group and a C₁-C₁₀ alkoxy group, each substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, and a phosphoric acid group or a salt thereof; a phenyl group; a naphthyl group; an anthryl group; a fluorenyl group; a pyrenyl group; and a phenyl group, a naphthyl group, an anthryl group, a fluorenyl group, and a pyrenyl group, each substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and C₁-C₁₀ alkoxy group.

In Formula 300, R₅₉ may be at least one of a phenyl group; a naphthyl group; an anthryl group; a biphenyl group; a pyridyl group; and a phenyl group, a naphthyl group, an anthryl group, a biphenyl group, and a pyridyl group, each substituted with at least one of a deuterium atom, a halogen atom, a hydroxyl group, a cyano group, —NO₂, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to another embodiment, the compound of Formula 300 may be represented by Formula 300 Å below:

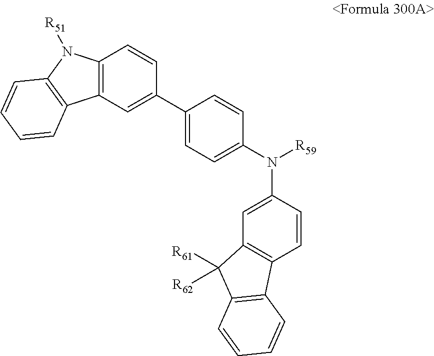

In Formula 300 Å, detailed descriptions of R₅₁, R₆₁, R₆₂, and R₅₉ may be defined as described above.

In some embodiments, at least one of the HIL, the HTL, and the H-functional layer may include at least one of Compounds 301 to 320 below:

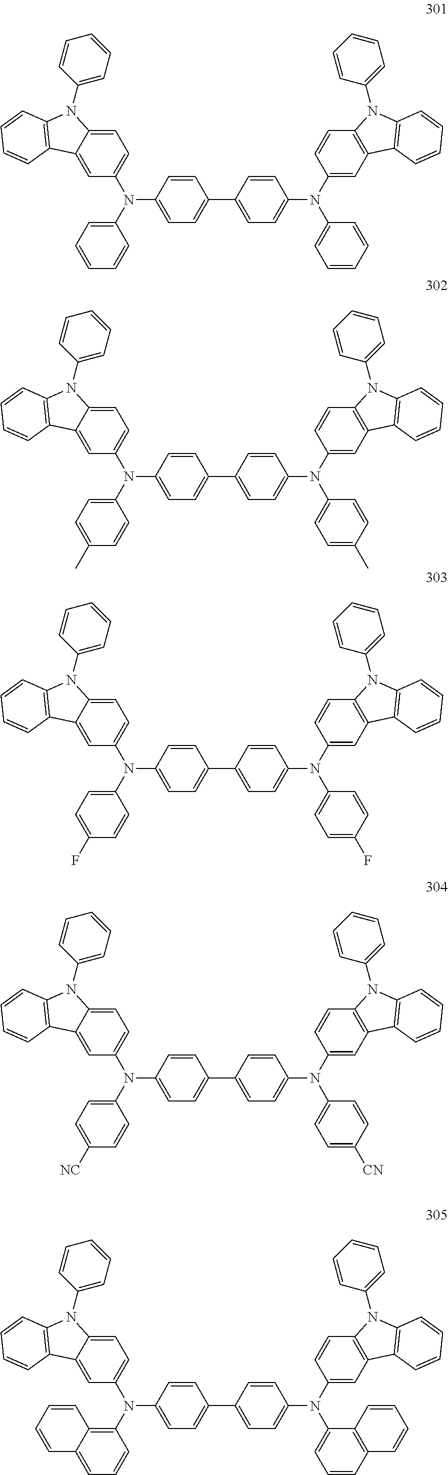

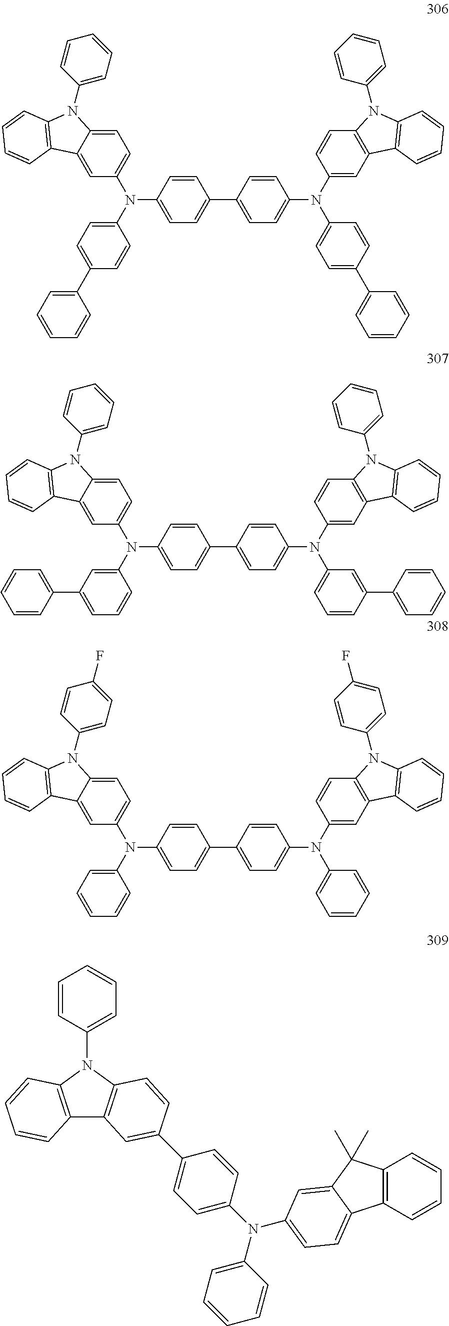 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

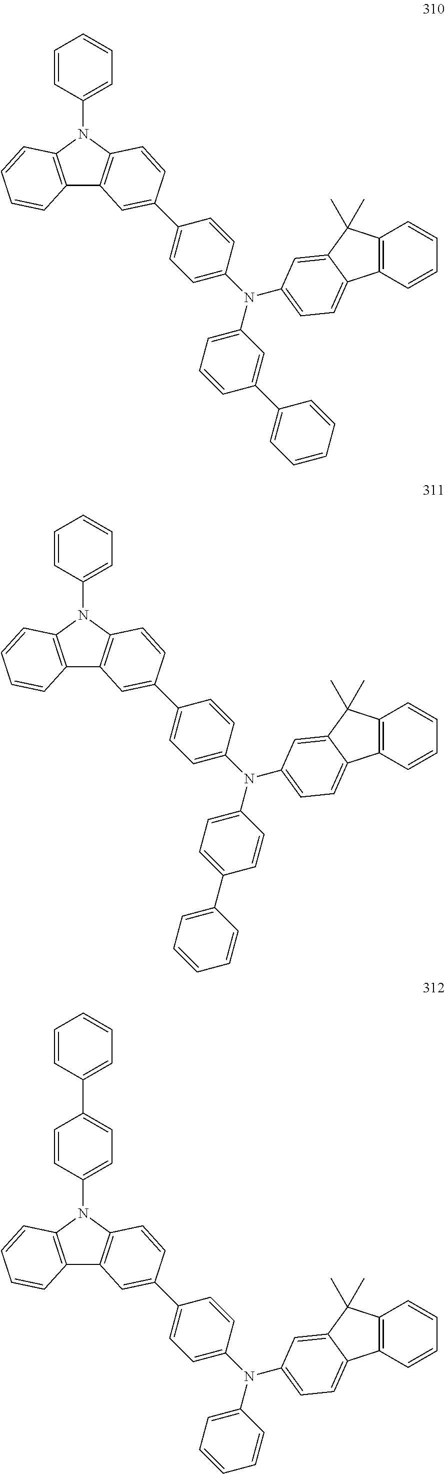 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

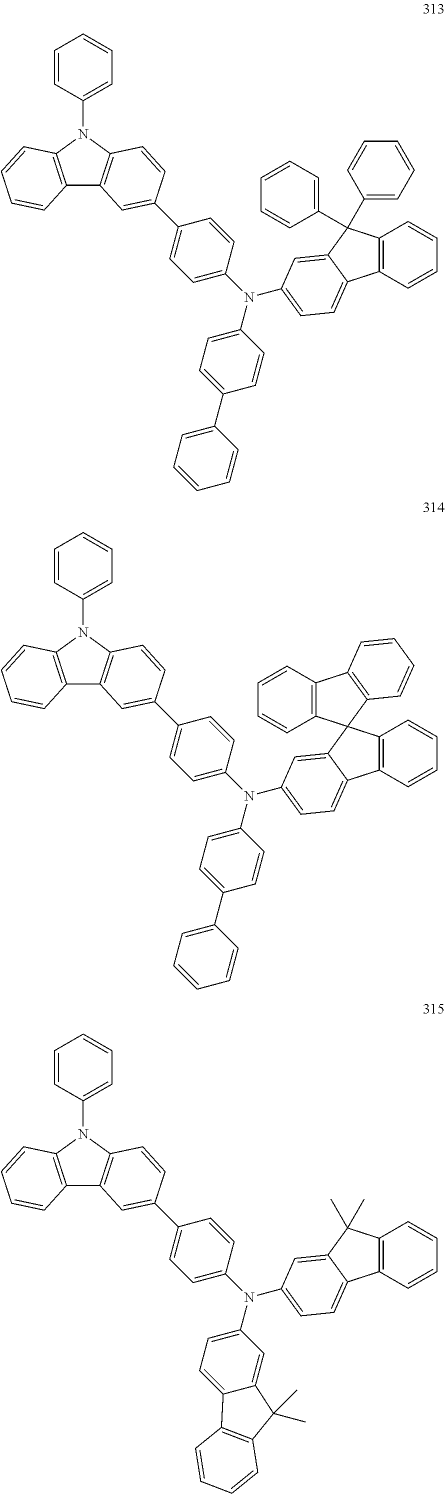 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

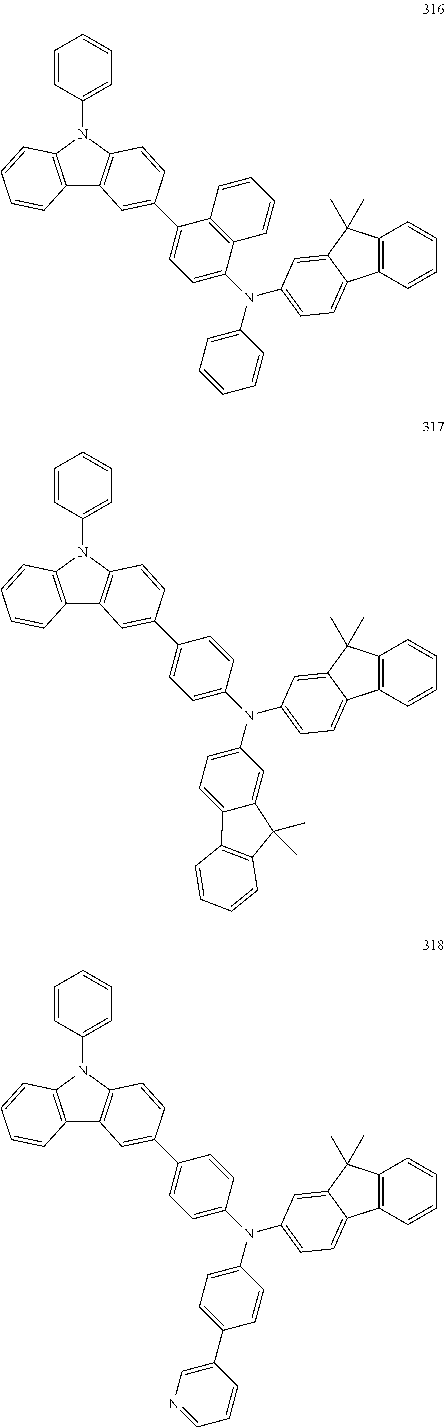 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

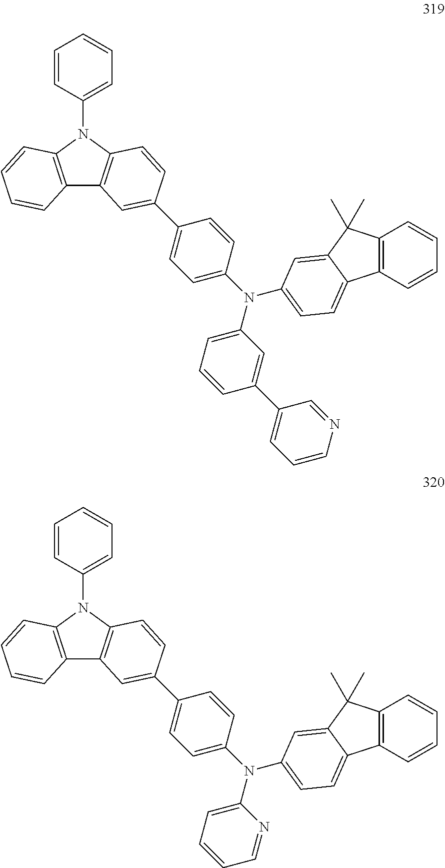 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, the HTL, and the H-functional layer may further include a charge-generating material to improve conductivity of a film, in addition to the above-described hole-injecting materials, hole-transporting materials, and/or materials having both hole-injecting and hole-transporting capabilities at the same time.

The charge-generating material may be, for example, a p-dopant. The p-dopant may be one of a quinone derivative, a metal oxide, and a cyano group-containing compound. Examples of the p-dopant include a quinone derivative, such as tetracyanoquinodimethane (TCNQ) and 2,3,5,6-tetrafluoro-tetracyano-1,4-benzoquinodimethane (F4-TCNQ); a metal oxide, such as a tungsten oxide and a molybdenym oxide; and a cyano group-containing group such as Compound 200 below:

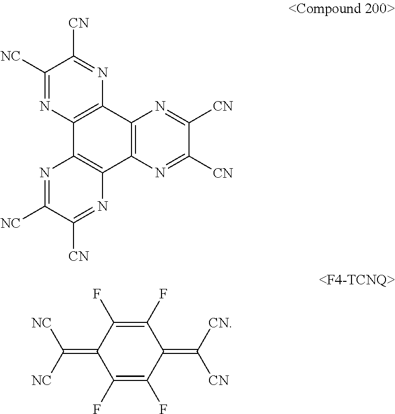

When the HIL, the HTL, or the H-functional layer further includes the charge-generating material, the charge-generating material may be homogeneously dispersed or non-homogeneously distributed in the layers above.

The buffer layer may be disposed between at least one of the HIL, the HTL, and the H-functional layer, and the EML. The buffer layer may compensate for an optical resonance distance of light according to a wavelength of the light emitted from the EML, and may increase efficiency. The buffer layer may include a hole-injecting material or hole-transporting material. In some other embodiments, the buffer layer may include the same material as one of the materials included in one of the HIL, the HTL, and the H-functional layer that underlie the buffer layer.

Then, the EML may be formed on the HTL, the H-functional layer, or the buffer layer by vacuum deposition, spin coating, casting, or LB deposition. When the EML is formed by vacuum deposition and spin coating, deposition and coating conditions may be similar to those for the formation of the HIL, although the conditions may vary depending on a compound that is used to form the EML.

The EML may include at least one iridium complex.

The iridium complex according to an embodiment included in the EML may act as a dopant (i.e., a red phosphorescent dopant). The EML may further include a host in addition to the iridium complex according to an embodiment.

The host may, for example, tris(8-quinolinorate)aluminum (Alq₃), 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene) (TPBI), 3-tert-butyl-9,10-di(naph-2-yl)anthracene (TBADN), mCP, or OXD-7:

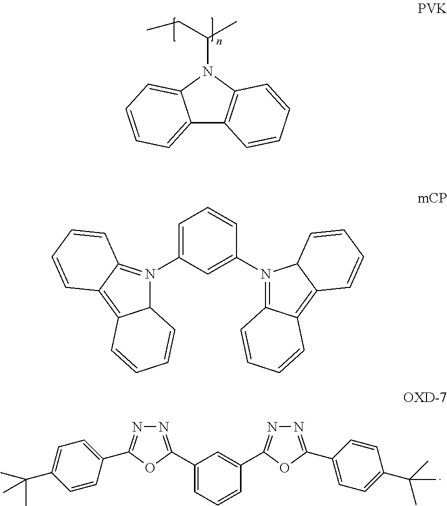

In some embodiments, a carbazole-based compound represented by Formula 10 below may be used as the host:

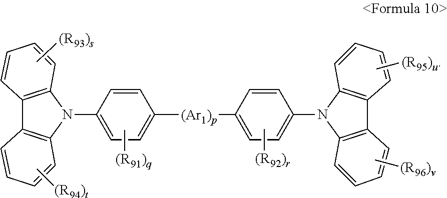

In Formula 10, Ar₁ may be a substituted or unsubstituted C₁-C₆₀ alkylene group, a substituted or unsubstituted C₂-C₆₀ alkenylene group, —C(═O)—, —N(R₁₀₀)—(here, R₁₀₀ may be a substituted or unsubstituted C₆-C₆₀ aryl group or a substituted or unsubstituted C₂-C₆₀ heteroaryl group), a substituted or unsubstituted C₆-C₆₀ arylene group, or a substituted or unsubstituted C₂-C₆₀ heteroarylene group;

p may be an integer of 0 to 10;

R₉₁ to R₉₆ may each independently be a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, or a substituted or unsubstituted C₂-C₆₀ heteroaryl group,

wherein two adjacent substituents among R₉₁ to R₉₆ may be connected to each other and optionally form a substituted or unsubstituted C₄-C₂₀ alicyclic ring, a substituted or unsubstituted C₂-C₂₀ heteroalicyclic ring, a substituted or unsubstituted C₆-C₂₀ aromatic ring, or a substituted or unsubstituted C₂-C₂₀ heteroaromatic ring; and

q, r, s, t, u, and v may each independently be an integer of 1 to 4.

In Formula 10, Ar₁ may be selected from a C₁-C₅ alkylene group, a C₂-C₅ alkenylene group, —C(═O)—, or —N(R₁₀₀)—. R₁₀₀ may be at least one of

a phenyl group, a naphthyl group, an anthryl group, a fluorenyl group, a carbazole group, a pyridinyl group, a pyrimidinyl group, and a triazinyl group; and

a phenyl group, a naphthyl group, an anthryl group, a fluorenyl group, a carbazole group, a pyridinyl group, a pyrimidinyl group, and a triazinyl group, each substituted with at least one of a deuterium atom, a halogen atom, a hydroxyl group, a cyano group, a nitro group, an amino group, a C₁-C₂₀ alkyl group, a C₁-C₂₀ alkoxy group, a phenyl group, a naphthyl group, an anthryl group, a fluorenyl group, a carbazole group, a pyridinyl group, a pyrimidinyl group, and a triazinyl group.

In Formula 10, R₉₁ to R₉₆ may each independently be selected from

a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and a C₁-C₂₀ alkoxy group; and

a C₁-C₂₀ alkyl group and a C₁-C₂₀ alkoxy group, each substituted with at least one of a deuterium atom, a halogen atom, a hydroxyl group, a cyano group, a nitro group, and an amino group.

The carbazole-based compound may be one of Compounds H1 to H30 below:

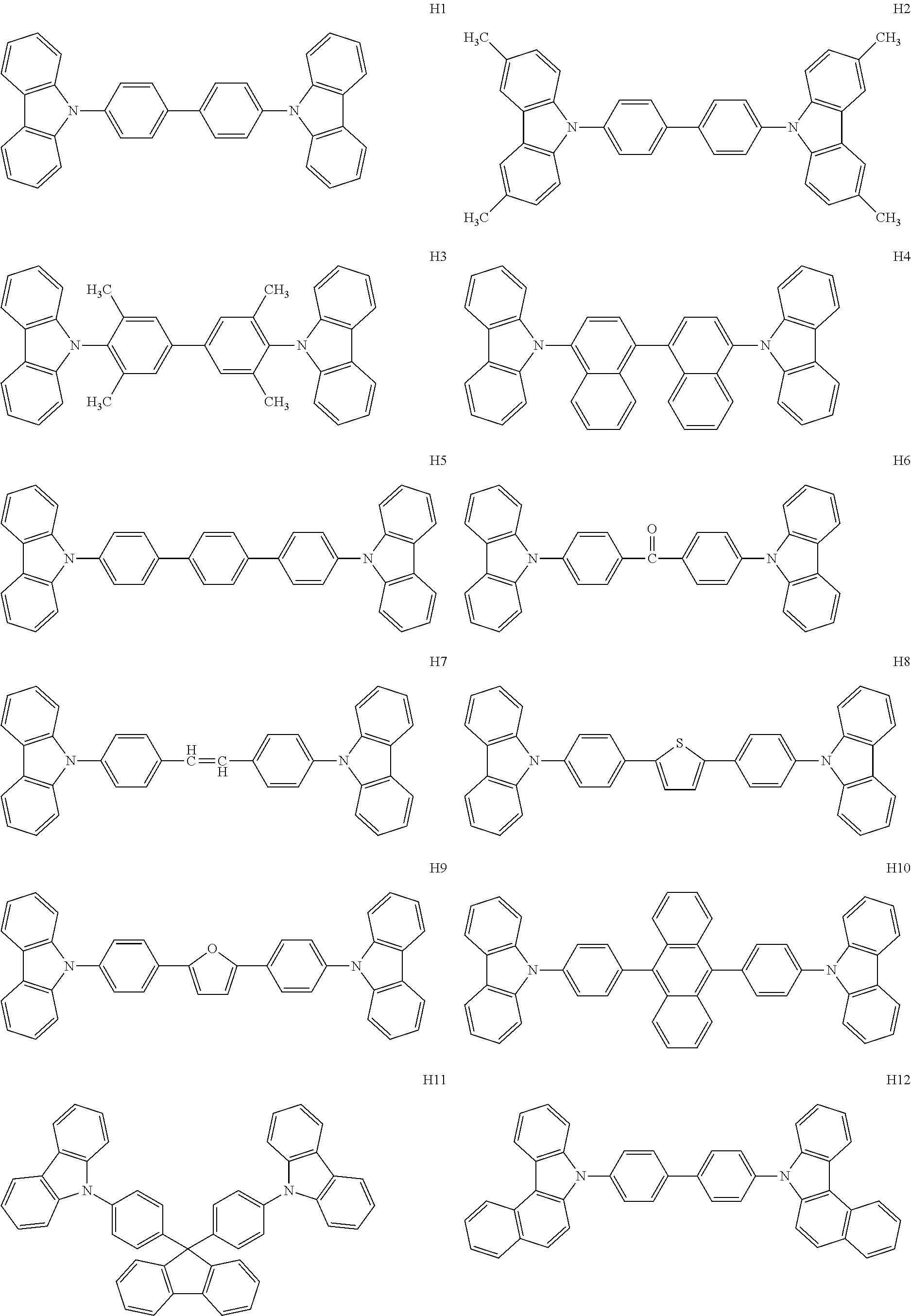

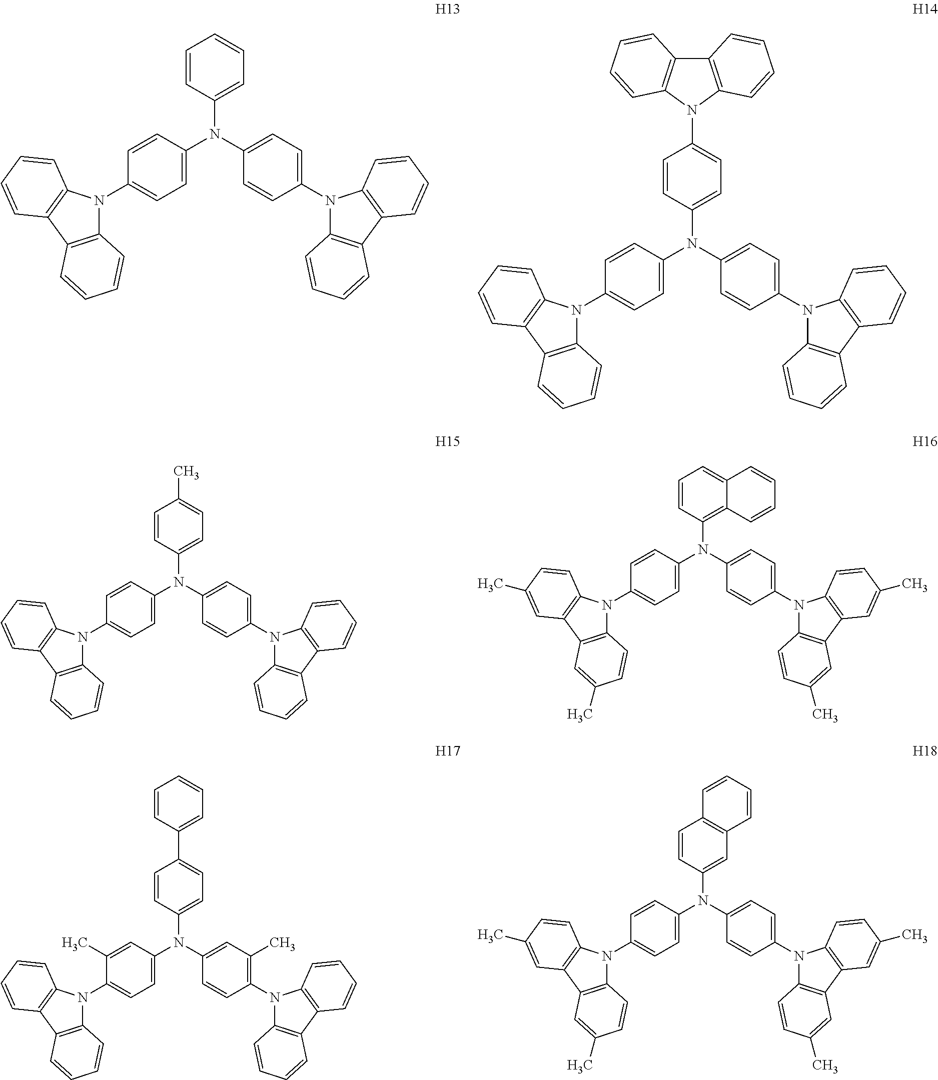

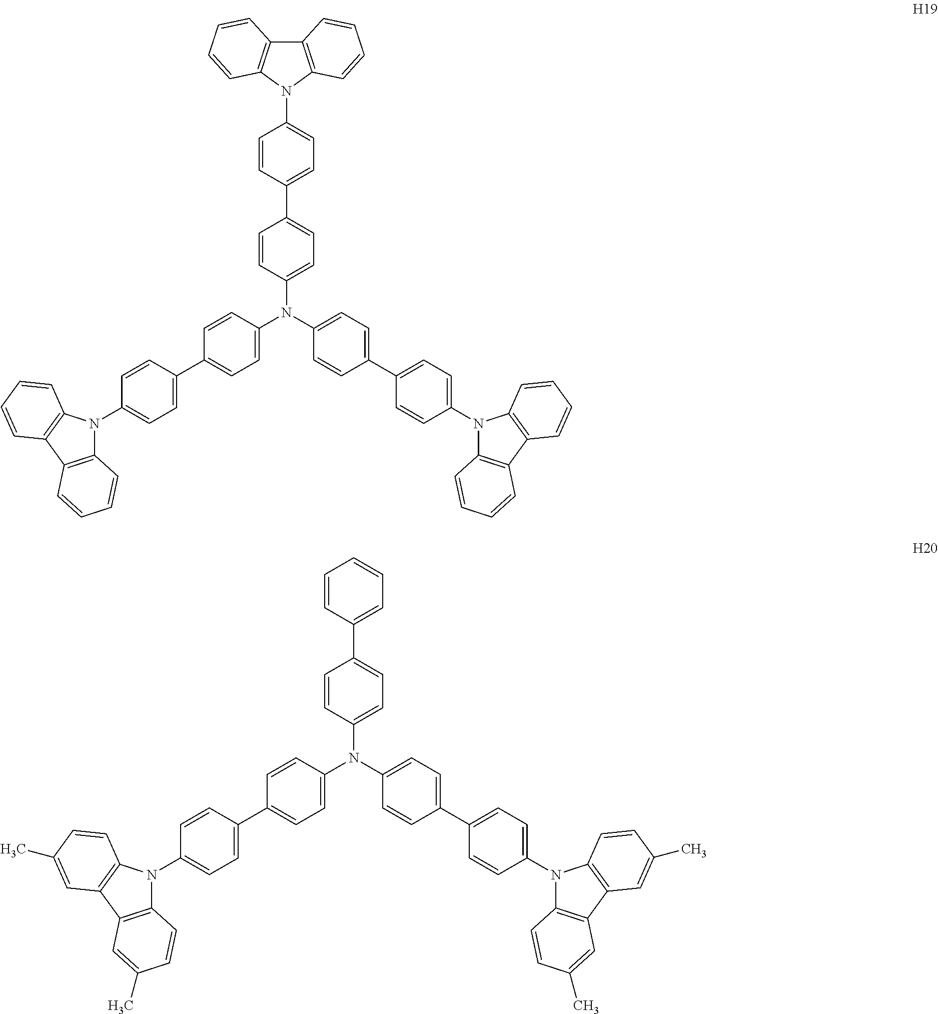

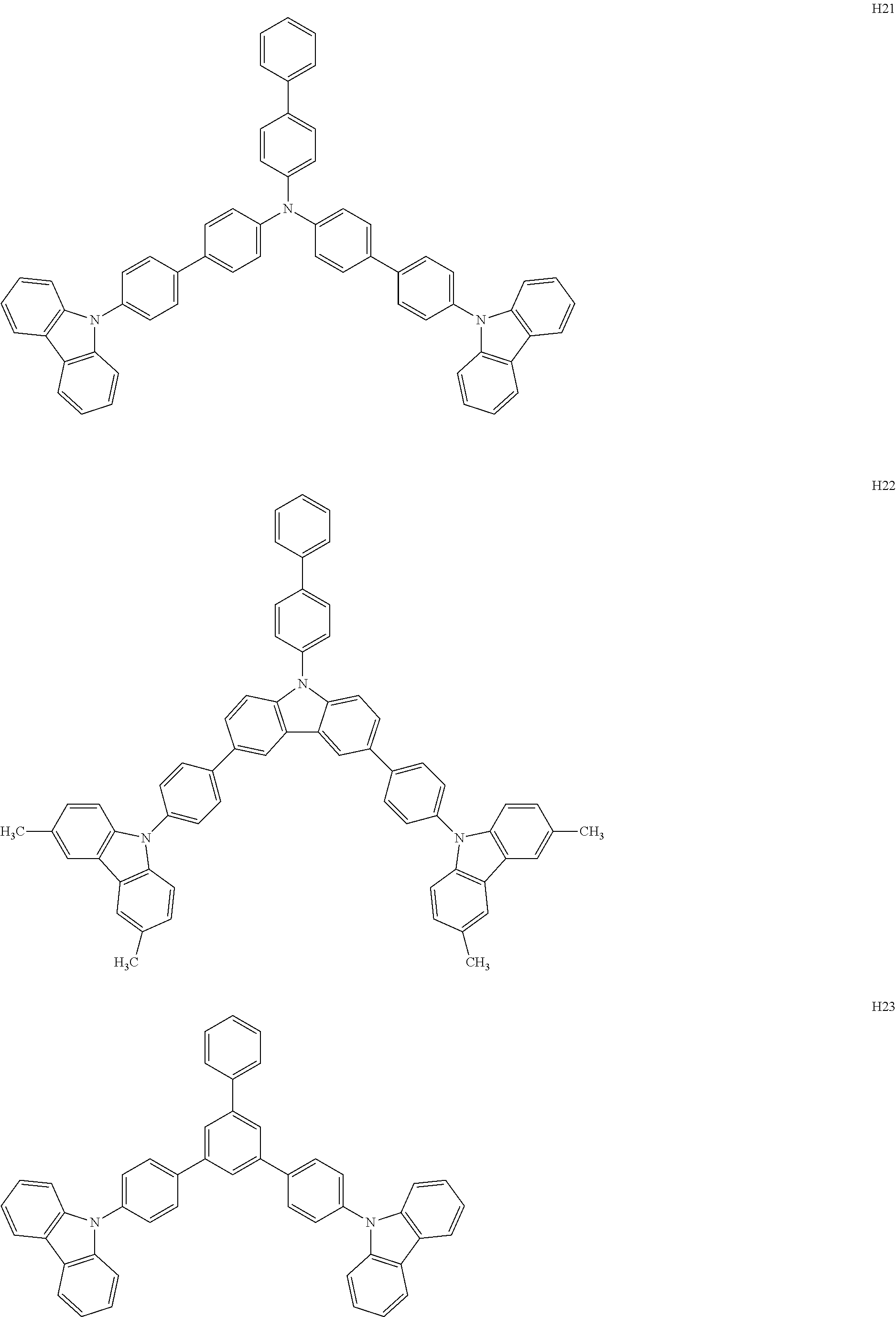

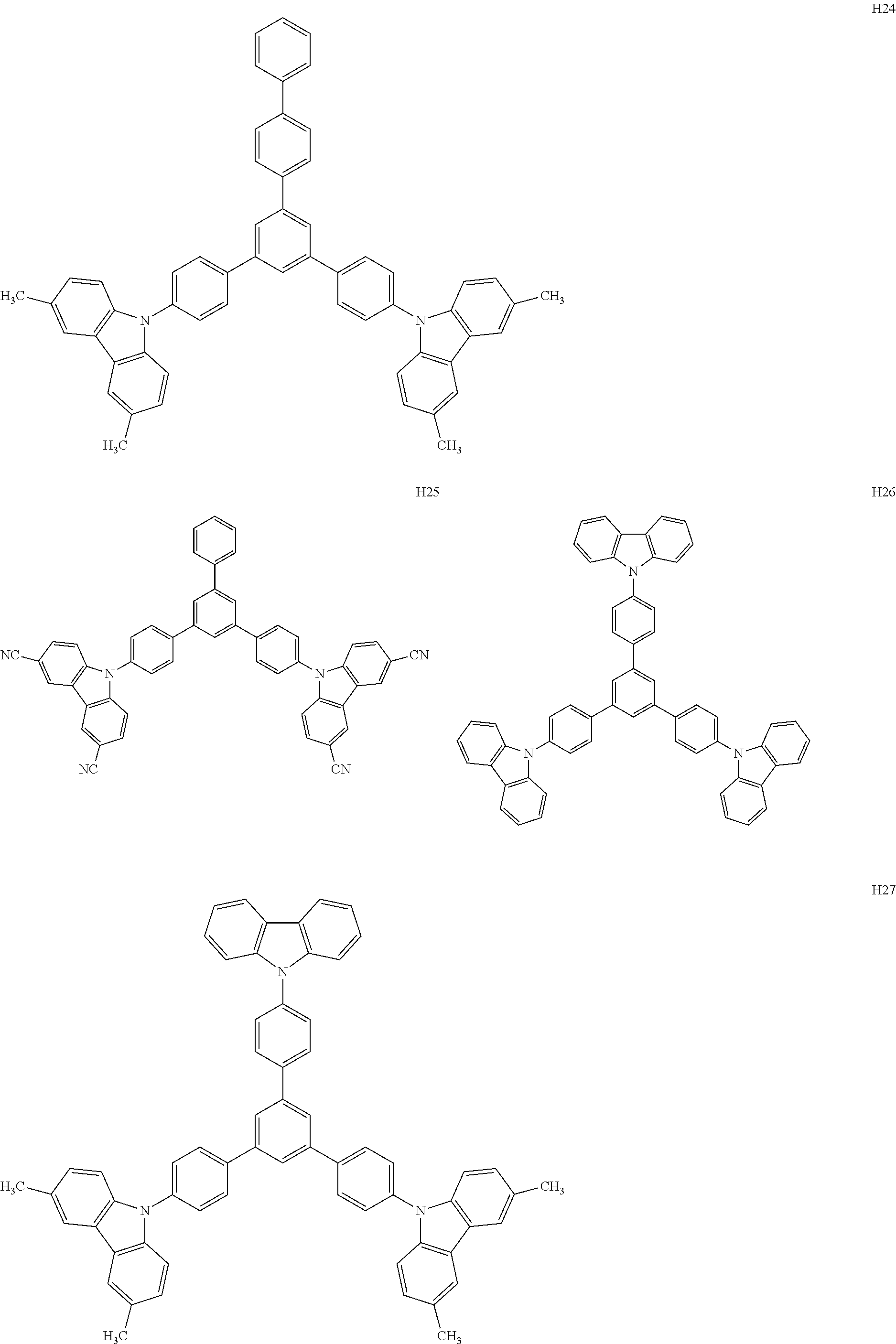

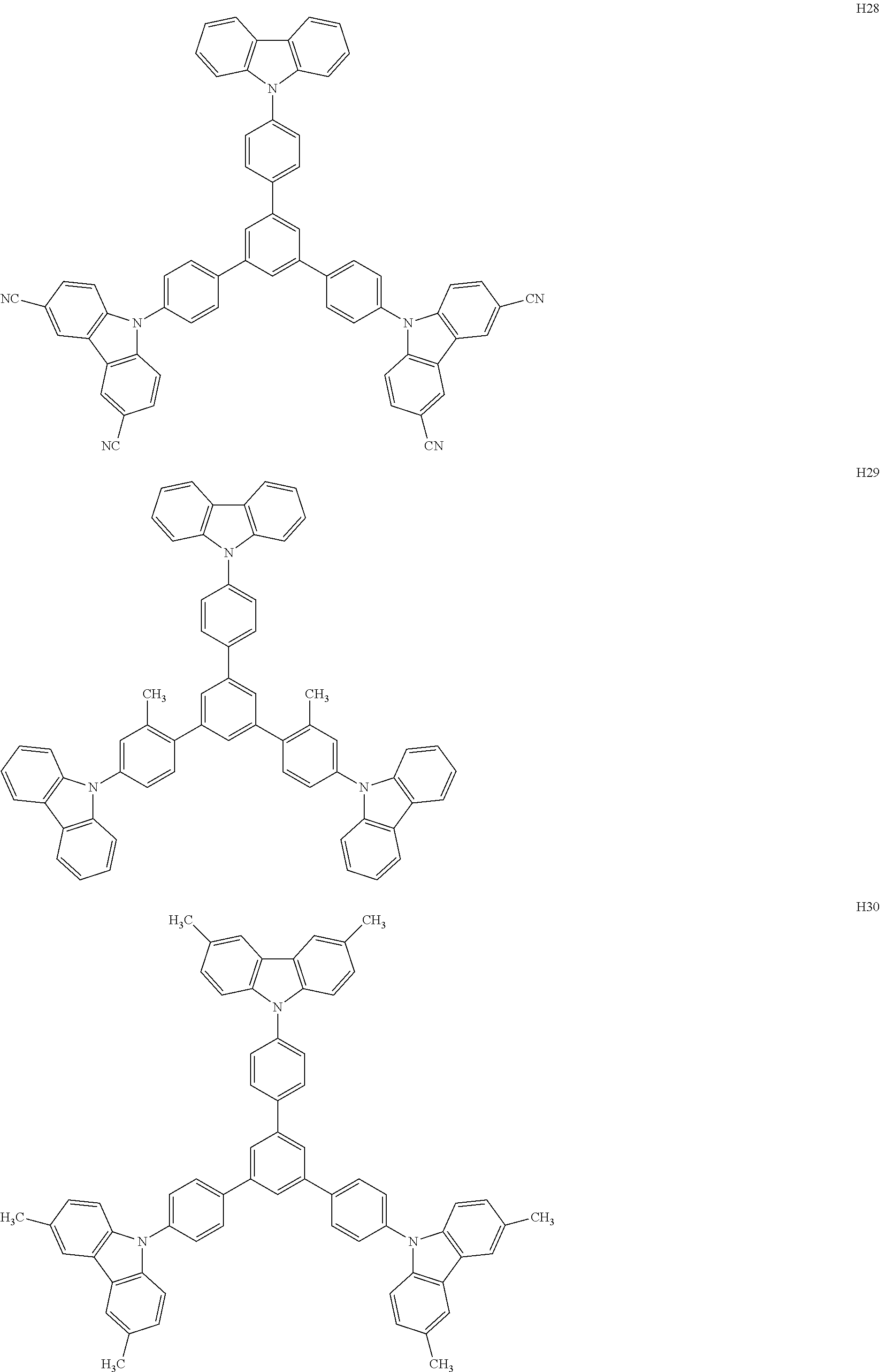

When the EML includes a host and a dopant (for example, the iridium complex of Formula 1), an amount of the dopant may be generally in a range from about 0.01 to about 15 wt % based on 100 wt % of the EML. For example, the amount of the dopant may be in a range from about 1 to about 15 wt % based on 100 wt % of the EML.

A thickness of the EML may be in a range from about 200 Å to about 700 Å. Maintaining the thickness of the EML within the above ranges may help provide the EML with satisfactory light-emitting ability without a substantial increase in a driving voltage.

Then, the ETL may be formed on the EML by using various methods, such as vacuum deposition, spin coating, or casting. When the ETL is formed by vacuum deposition and spin coating, deposition and coating conditions may be similar to those for the formation of the HIL, although the conditions may vary depending on a compound that is used to form the ETL. The electron-transporting material may be any material that can stably transport electrons injected from an electron-injecting electrode (cathode). Examples of the electron-transporting material are a quinoine derivative, such as Alq₃, TAZ, Balq, beryllium bis(benzoquinolin-10-olate (Bebq₂), ADN, Compound 101, Compound 102, and Bphen:

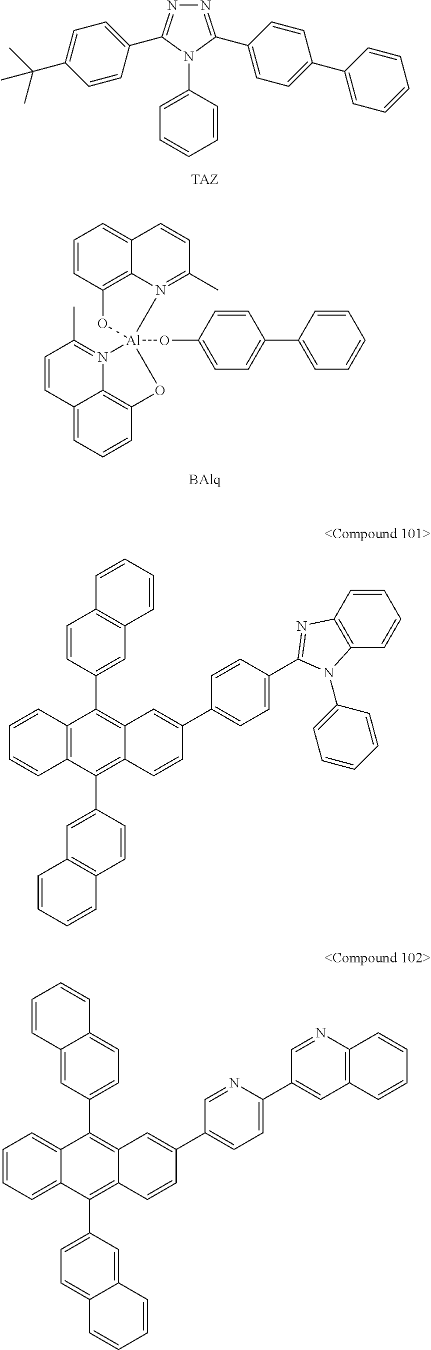

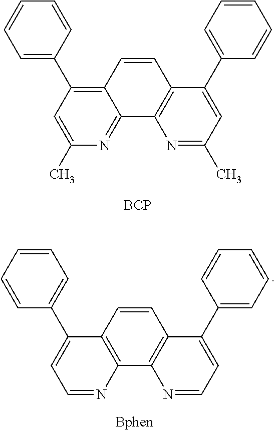 [SMILES: Cc1cc(-c2ccccc2)c2ccc3c(-c4ccccc4)cc(C)nc3c2n1 ; "BCP" ; c1ccc(-c2ccnc3c2ccc2c(-c4ccccc4)ccnc23)cc1]

A thickness of the ETL may be in a range from about 100 Å to about 1,000 Å, for example, about 150 Å to about 500 Å. Maintaining the thickness of the ETL within the above ranges may help provide the ETL with satisfactory electron-transporting ability without a substantial increase in a driving voltage.

In some embodiments, the ETL may further include a metal-containing material in addition to an electron-transporting organic compound.

The metal-containing material may include a Li complex. Examples thereof include lithium quinolate (LiQ) and Compound 203 below:

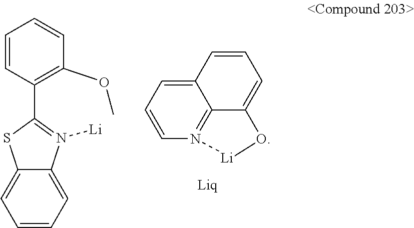

Also, the EIL, which facilitates an injection of electrons from the cathode, may be disposed on the ETL. Any suitable electron-injecting material may be used to form the EIL.

Materials such as, for example, LiF, NaCl, CsF, Li₂O, and BaO, may be used as an electron-injecting material. Vacuum deposition conditions of the EIL may be similar to those for the formation of the HIL, although the deposition conditions may vary depending on a compound that is used to form the EIL.

A thickness of the EIL may in a range from about 1 Å to about 100 Å, for example, about 3 Å to about 90 Å. Maintaining the thickness of the EIL within the above ranges may help provide the EIL with satisfactory electron-injecting ability without a substantial increase in a driving voltage.

A second electrode may be disposed on the organic layer. The second electrode may be a cathode, for example, an electron-injecting electrode. A second electron-forming material may be a metal, an alloy, an electro-conductive compound, which may have a low work function, or a mixture thereof. In this regard, the second electrode may be formed of lithium (Li), magnesium-aluminum (Mg—Al), alimunium-lithium (Al—Li), calcium (Ca), magnesium-indium (Mg—In), or magnesium-silver (Mg—Ag), and may be formed as a thin film type transmission electrode. In some embodiments, to manufacture a top-emission light-emitting device, the transmission electrode may be formed of indium tin oxide (ITO) or indium zinc oxide (IZO).

The organic light-emitting device 10 has been described with reference to FIG. 4. Additional embodiments include omission of one or more of the layers illustrated in FIG. 4 (i.e., EIL, ETL, EML, HTL, and HIL), rearrangement of one or more of the layers illustrated in FIG. 4, and/or additional layers.

For example, when a phosphorescent dopant is used in the EML, a hole blocking layer (HBL) may be formed between the ETL and EML or between the E-functional layer and the EML by using vacuum deposition, spin coating, casting, or LB deposition, in order to prevent diffusion of tiplet excitons or holes toward the ETL. When the HBL is faulted by vacuum deposition and spin coating, deposition and coating conditions may be similar to those for the formation of the HIL, although the conditions may vary according to a compound that is used to form the HBL. A hole-blocking material may be used. Examples thereof include oxadiazole derivates, triazole derivatives, and phenanthroline derivatives. In some embodiments, BCP shown below may be used as a hole-blocking material.

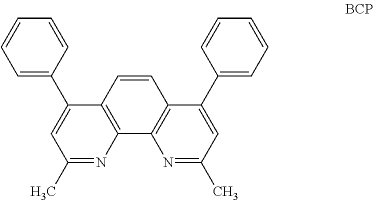 [SMILES: Cc1cc(-c2ccccc2)c2ccc3c(-c4ccccc4)cc(C)nc3c2n1]

A thickness of the HBL may be in a range from about 20 Å to about 1,000 Å, for example, about 30 Å to about 300 Å. Maintaining the thickness of the HBL within the above ranges may help provide the HBL with good hole-blocking ability without a substantial increase in a driving voltage.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1

### Synthesis of Complex 1

Synthesis of Intermediate Complex 1-1

Intermediate Complex 1-1 was Synthesized According to Reaction Scheme 1(1) Below:

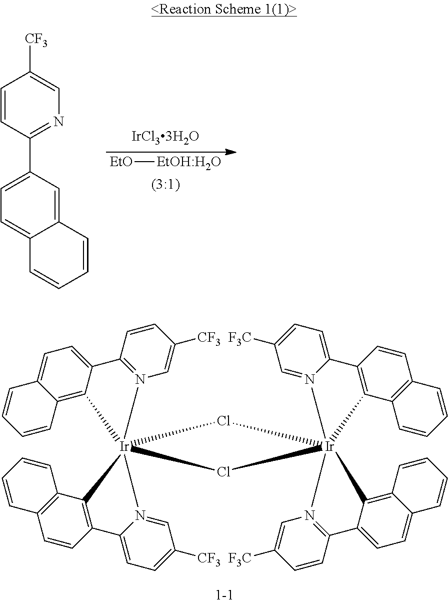

After dissolving 5.0 g (18.3 mmol) of 2-(naphthalen-2-yl)-5-(trifluoromethyl)pyridine in 45 mL of 2-ethoxyethanol, 2.4 g (7.6 mmol) of iridiumchloride hydrate and 15 mL of distilled water were added thereto, and then the reaction solution was stirred at a temperature of 130° C. for 20 hours. After completion of the reaction, the reaction solution was cooled down to room temperature and filtered precipitates. The precipitates were then washed out with methanol and dried under vacuum to obtain 4.8 g of Intermediate 1-1.

### Synthesis of Complex 1

Complex 1 was Synthesized According to Reaction Scheme 1(2) Below:

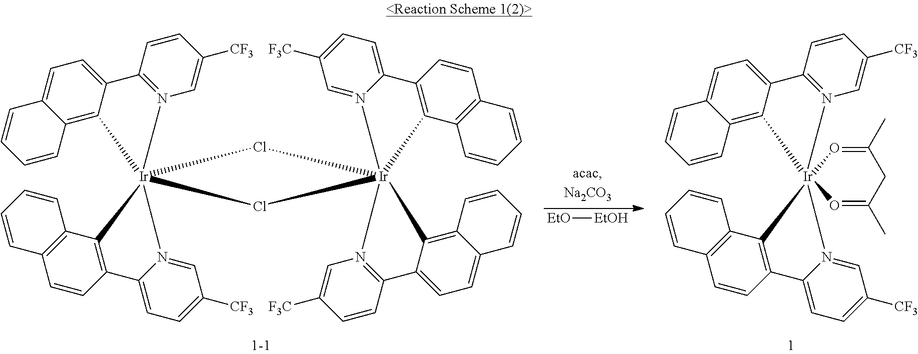

1.0 g (1.03 mmol) of the Intermediate 1-1, 0.24 g (2.44 mmol) of acetylacetonate, and 0.34 g (2.46 mmol) of Na₂CO₃ were added to 30 mL of a 2-ethoxyethanol solution, and then the reaction solution was stirred at a temperature of 130° C. for 12 hours. After completion of the reaction, the reaction solution was cooled down to room temperature and filtered precipitates. The precipitates were then washed out with methanol and dissolved in a dichloromethane solution to filter with a silica short pad. The filtered dichloromethane solution was slowly heated again, and methanol was slowly added thereto to precipitate and obtain 0.70 g of a phosphorescent complex represented by Formula 1 above.

¹H-NMR: 8.46 (2H), 8.31 (2H), 8.14 (2H), 8.06 (4H), 7.96 (2H), 7.54 (4H), 7.36 (2H), 2.12 (6H) APCI-MS (m/z): [M+] 835

### Synthesis Example 2

### Synthesis of Complex 2

Synthesis of Complex 2

Complex 2 was Synthesized According to Reaction Scheme 2 Below:

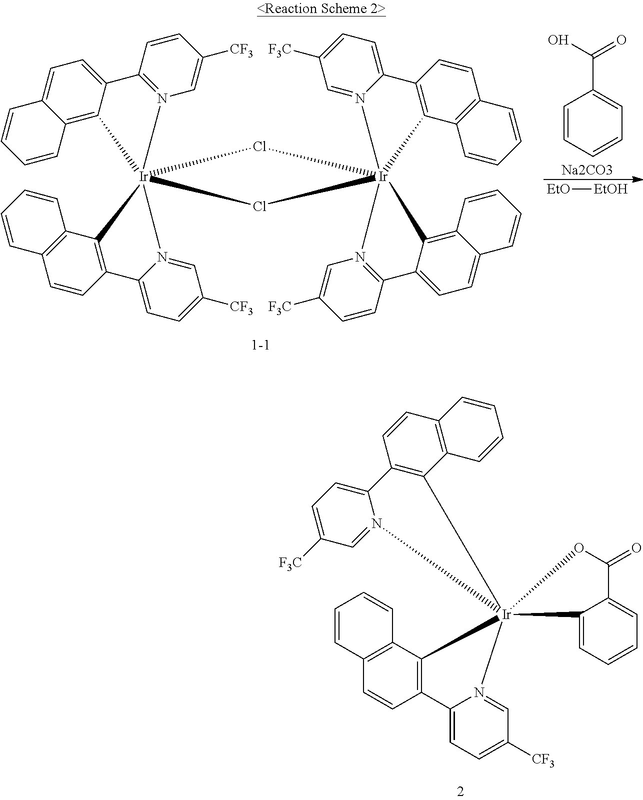

1.0 g (1.03 mmol) of the Intermediate 1-1, 0.3 g (2.44 mmol) of benzoic acid, and 0.34 g (2.46 mmol) of Na₂CO₃ were added to 30 mL of a 2-ethoxyethanol solution, and then the reaction solution was stirred at a temperature of 130° C. for 12 hours. After completion of the reaction, the reaction solution was cooled down to room temperature and filtered precipitates. The precipitates were then washed out with methanol and dissolved in a dichloromethane solution to filter with a silica short pad. The filtered dichloromethane solution was slowly heated again, and methanol was slowly added thereto to precipitate and obtain 0.78 g of a phosphorescent complex represented by Formula 2 above.

¹H-NMR: 8.44 (2H), 8.30 (2H), 8.21 (1H), 8.15 (2H), 8.08 (4H), 7.96 (2H), 7.79 (1H), 7.66 (2H), 7.54 (4H), 7.36 (2H), 2.12 (6H) APCI-MS (m/z): [M+] 857

### Synthesis Example 3

### Synthesis of Complex 3

Synthesis of Complex 3

Complex 3 was Synthesized According to Reaction Scheme 3 Below:

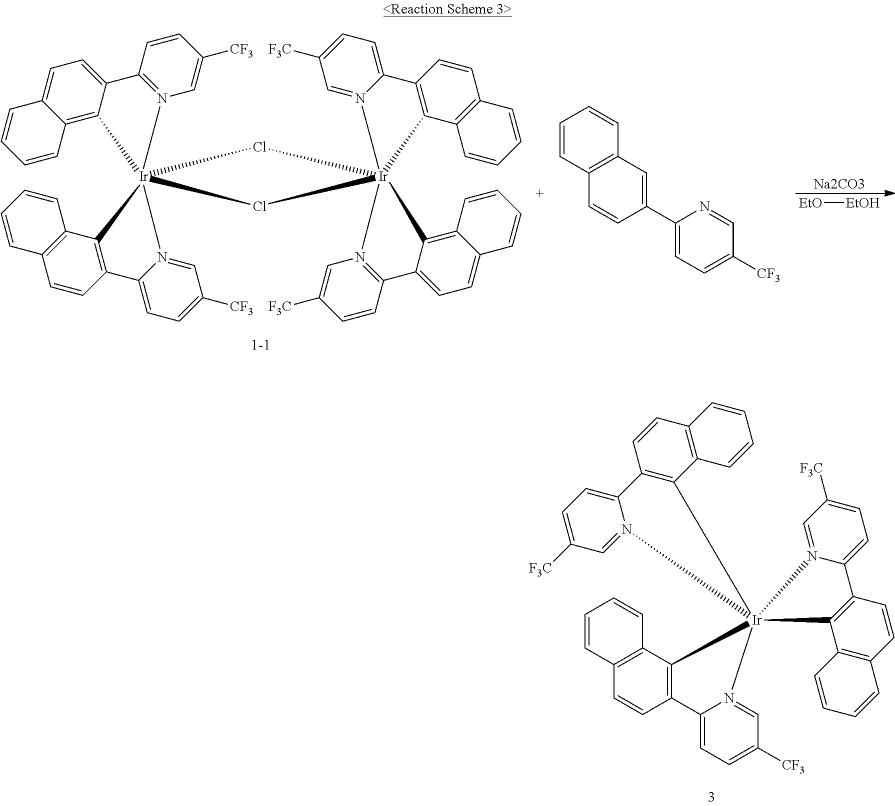

1.0 g (1.03 mmol) of the Intermediate 1-1, 0.67 g (2.44 mmol) of 2-(naphthalen-2-yl)-5-(trifluoromethyl)pyridine, and 0.34 g (2.46 mmol) of Na₂CO₃ were added to 30 mL of a 2-ethoxyethanol solution, and then the reaction solution was stirred at a temperature of 130° C. for 12 hours. After completion of the reaction, the reaction solution was cooled down to room temperature and filtered precipitates. The precipitates were then washed out with methanol and dissolved in a dichloromethane solution to filter with a silica short pad. The filtered dichloromethane solution was slowly heated again, and methanol was slowly added thereto to precipitate and obtain 0.70 g of a phosphorescent complex represented by Formula 1 above.

¹H-NMR: 8.44 (311), 8.31 (3H), 8.14 (3H), 8.06 (3H), 7.96 (314), 7.54 (6H), 7.36 (3H), APCI-MS (m/z): [M+] 1009

### Evaluation Example 1

### Evaluation on Light-Emitting Characteristics of Complex 1 in Solution

Ultraviolet (UV) absorption spectrum and photoluminescence (PL) spectrum of

Complex 1 of Synthesis Example 1 were analyzed to evaluate light-emitting ability of Complex 1. First, Complex 1 was diluted to a concentration of 0.2 mM in toluene, followed by measuring UV spectrum of Complex 1 in solution by using Shimadzu UV-350 Spectrometer).

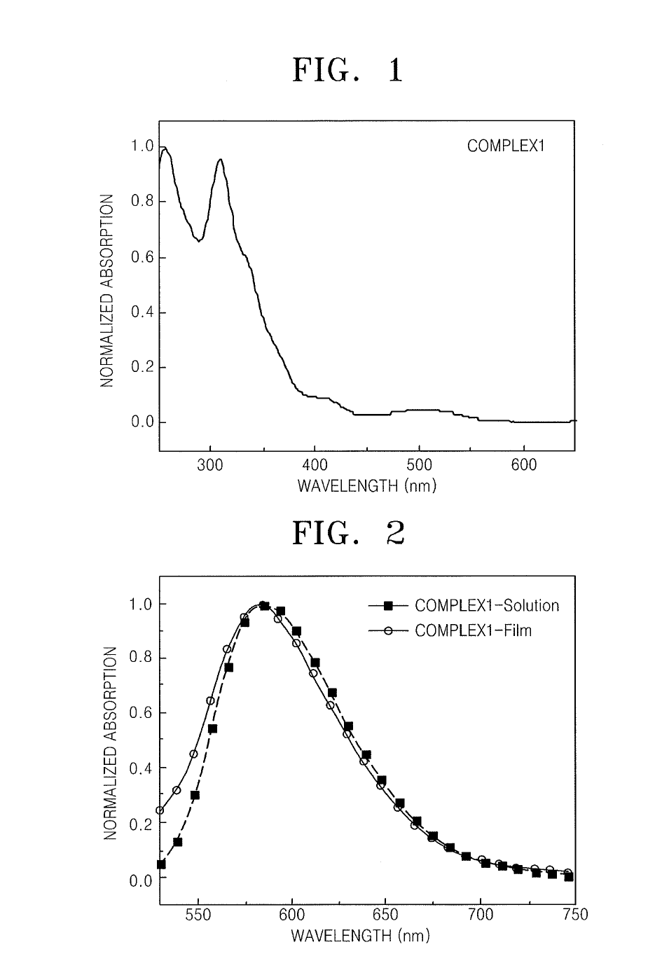

Meanwhile, Complex 1 was diluted to a concentration of 100 mM in toluene, followed by measuring PL spectrum of Complex 1 in solution by using ISC PC1 Spectrofluorometer that is equipped with Xenon lamp. PL spectrum of Complex 1 film was also measured. The results of the measurements are shown in FIGS. 1 and 2.

According to FIGS. 1 and 2, Complex 1 was found to have excellent UV absorption and PL emission abilities.

### Evaluation Example 2

### Evaluation on Electrical Characteristics of Complex 1

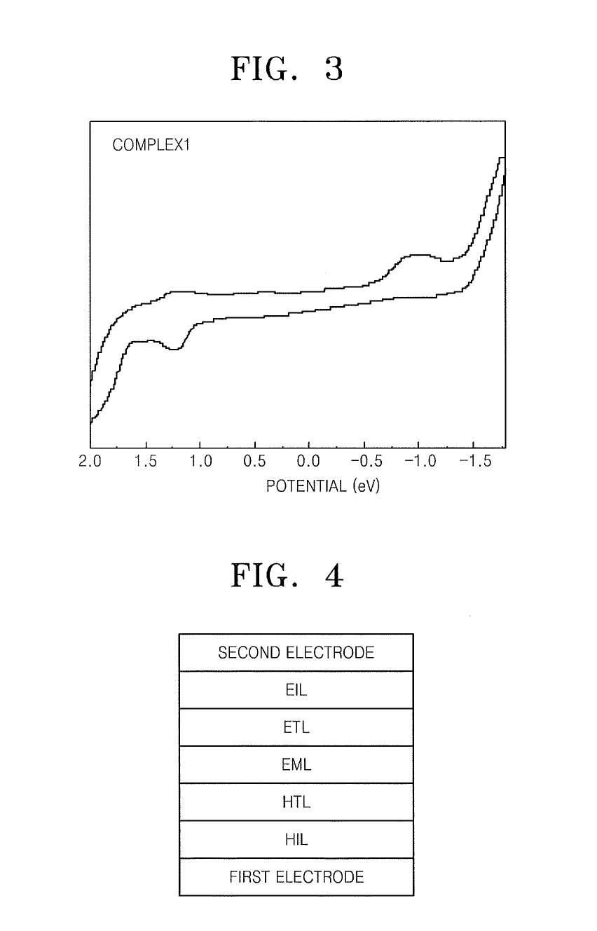

Electrical characteristics of Complex 1 were evaluated by Cyclic voltammetry (CV) (electrolyte: 0.1 M Bu₄NClO₄/solvent: CH₂Cl₂/electrode: a third electrode system (working electrode: GC, reference electrode: Ag/AgCl, auxiliary electrode: Pt)), and the results of the measurements are each shown in FIG. 3.

Referring to FIG. 3, Complex 1 was found to be suitable for use as a compound for an OLED with its appropriate electrical abilities.

### Example 1

As an anode, a Corning 15 Ω/cm2 (1200 Å) ITO glass substrate was cut into a size of 50 mm×50 mm x 0.7 mm, followed by ultrasonic cleaning each for 5 minutes using isopropyl alcohol and pure water. After UV irradiation for 30 minutes and exposure to ozone for cleaning, the glass substrate was loaded into a vacuum deposition device.

2-TNATA, a hole-injecting material, was vacuum-deposited on the substrate to form an HIL having a thickness of 600 Å, and 4′-bis[N-(1-naphthyl)-N-phenylamino]biphenyl (hereinafter, NPB), a hole-transporting material, was vacuum-deposited on the HIL to form an HTL having a thickness of 300 Å.

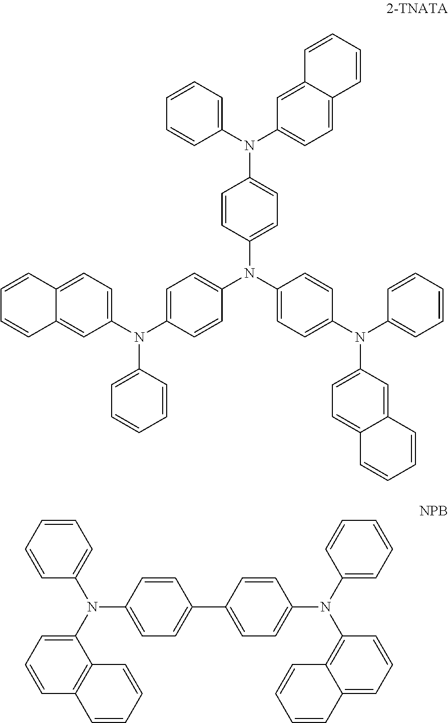

CBP, which is a phosphorescent host, and iridium Complex 1 were co-deposited at a weight ratio of 98:2 on the HTL to form an EML having a thickness of 400 Å. Next, Compound 101 was deposited on the EML to form an ETL having a thickness of 300 Å, and then LiF, which is a halogenated alkali metal, was deposited on the ETL to form an EIL having a thickness of 10 Å. Then, Al was vacuum-deposited on the EIL to form an anode electrode having a thickness of 3,000 Å, thereby forming a LiF/Al electrode and completing the manufacture of an OLED.

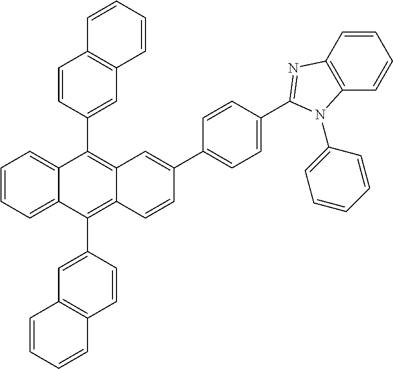 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### Example 2

An OLED was manufactured in the same manner as in Example 1, except that Complex 2, instead of Complex 1, was used to form the EML.

### Example 3

An OLED was manufactured in the same manner as in Example 1, except that Complex 3, instead of Complex 1, was used to form the EML.

### Comparative Example 1

An OLED was manufactured in the same manner as in Example 1, except that Complex 102, instead of Complex 1, was used to form the EML.

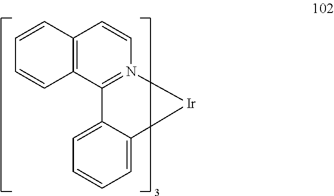

### Comparative Example 2

An OLED was manufactured in the same manner as in Example 1, except that Complex 103, instead of Complex 1, was used to form the EML.

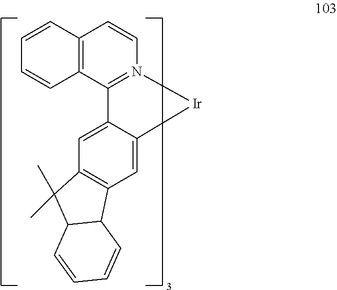

### Evaluation Example 3

Efficiencies and color purities of the OLEDs of Examples 1 to 3 and Comparative Examples 1 and 2 were evaluated by using a luminance meter (PR650 Spectroscan Source Measurement Unit, available from PhotoResearch, Inc.). The results of the measurements are shown in Table 1 below.

TABLE 1

| | | Driving | Efficiency |
|---|---|---|---|
| | | voltage | (cd/A) |
| | Dopant | at 10 mA/m² | at 10 mA/m² |
| Example 1 | Complex 1 | 4.2 | 40.2 |
| Example 2 | Complex 2 | 4.4 | 36.3 |
| Example 3 | Complex 3 | 4.7 | 32.1 |
| Comparative | Complex 102 | 6.6 | 18.6 |
| Example 1 | | | |
| Comparative | Complex 103 | 7.2 | 15.3 |
| Example 2 | | | |

Referring to Table 1 above, it may be concluded that the OLED including Complex 1, 2, or 3 of Formula 1 according to an embodiment have high efficiency and excellent color purity characteristics compared to those including Complex 102 or 103.

By way of summation and review, an OLED device may have a structure including a substrate, an anode formed on the substrate, and a hole transport layer, an emission layer, an electron transport layer, and a cathode which are sequentially stacked on the anode. The hole transport layer, the emission layer, and the electron transport layer are organic thin films formed of organic compounds.

When a voltage is applied between the anode and the cathode, holes injected from the anode pass the hole transport layer and migrate toward the emission layer, and electrons injected from the cathode pass the electron transport layer and migrate toward the emission layer. The holes and the electrons are recombined with each other in the emission layer to generate excitons. Then, the excitons are transitioned from an excited state to a ground state, thereby generating light.

Accordingly, provided is a phosphorescent iridium (Ir) complex and an organic light-emitting device (OLED) including the same. As described above, the phosphorescent iridium (Ir) Complex according embodiments may have excellent light-emitting ability, provide a variety of colors such as blue and red, and be a suitable light-emitting material to be used in a phosphorescent device. Therefore, an OLED having high efficiency, low driving voltage, high luminance, and long lifetime may be manufactured using the above-described material.

In addition, the iridium Complex according to an embodiment may have a high glass transition temperature (Tg) or a high melting point. Thus, in regard to electroluminescence, the iridium Complex according to an embodiment may increase its thermal resistance and high-temperature environment stability against Joule's heat that may be generated in an emission layer (organic layer), between emission layers, or between an emission layer and a metal electrode. An OLED manufactured using the iridium Complex according to an embodiment may have high durability during storage or operation.

A flat panel display device may include the presently disclosed OLED including the iridium Complex according to an embodiment. The first electrode of the OLED may be electrically connected to a source electrode or a drain electrode of a thin film transistor (TFT).

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An iridium complex represented by Formula 1: 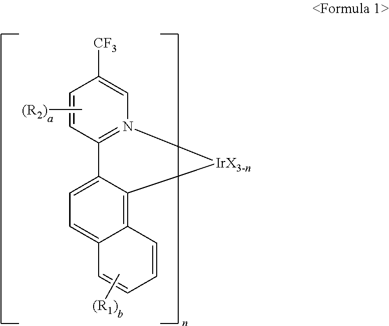
wherein:
R₁ and R₂ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₂-C₃₀ heteroaryl group;
X is a bidendate ligand having −1 valence;
a is an integer of 1 to 3; and
b is an integer of 1 to 6; and
n is 2 or 3;
provided that if a is 2 or greater, a plurality of R₂'s are optionally connected to each other to form a ring.

2. The iridium complex as claimed in claim 1, wherein R₁ and R₂ are each independently selected from:
i) a C₆-C₁₄ aryl group and a C₂-C₁₄ heteroaryl group; and
ii) a C₆-C₁₄ aryl group and a C₂-C₁₄ heteroaryl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a C₆-C₁₄ aryl group, and C₂-C₁₄ heteroaryl group.

3. The iridium complex as claimed in claim 1, wherein R₁ and R₂ are each independently selected from:
i) a phenyl group, a biphenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group; and
ii) a phenyl group, a biphenyl group, a naphthyl group, an anthryl group, a pyrenyl group, a phenanthrenyl group, a fluorenyl group, a pyridinyl group, a bipyridinyl group, a terpyridinyl group, a pyrazinyl group, a pyrimidinyl group, a triazinyl group, a quinolinyl group, an isoquinolinyl group, a quinoxalinyl group, a phenanthrolinyl group, and a carbazole group, each substituted with at least one of a deuterium atom, a fluorine (F), a chlorine (Cl), a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a pyrenyl group, a phenanthrenyl group, a fluorenyl group, a pyridinyl group, a pyrazinyl group, a pyrimidinyl group, a triazinyl group, a quinolinyl group, an isoquinolinyl group, a quinoxalinyl group, a phenanthrolinyl group, and a carbazole group.

4. The iridium complex as claimed in claim 1, wherein:
R₁ and R₂ are each independently selected from a hydrogen atom, a deuterium atom, —CF₃, and Formula 2a: 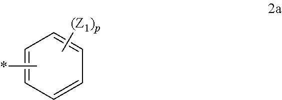
wherein in Formula 2a:
Z₁ is a hydrogen atom, a deuterium atom, a substituted or unsubstituted C₁-C₂₀ alkyl group, a substituted or unsubstituted C₅-C₂₀ aryl group, a substituted or unsubstituted C₃-C₂₀ heteroaryl group, a substituted or unsubstituted C₆-C₂₀ condensed polycyclic group, an amino group substituted with a C₅-C₂₀ aryl group or a C₃-C₂₀ heteroaryl group, a halogen atom, a cyano group, a nitro group, a hydroxyl group, or a carboxyl group;
p is an integer of 1 to 5; and
* indicates a binding site.

5. The iridium complex as claimed in claim 1, wherein the iridium complex of Formula 1 is represented by Formula 2: 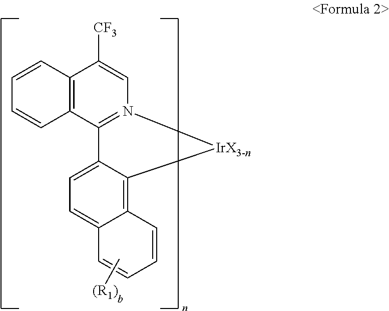
wherein, in Formula 2, substituents and symbols are each defined as described in claim 1.

6. The iridium complex as claimed in claim 1, wherein n is 2 and X is acetylacetonate, hexafluoroacetonate, tetramethylheptadionate, dibenzoylmethane, picolinate, salicylanilide, 8-hydroxyquinolate, or 1,5-dimethyl-3-pyrazole carboxylate.

7. The iridium complex as claimed in claim 1, wherein n is 2 and X is represented by Formula 3a or Formula 3b: 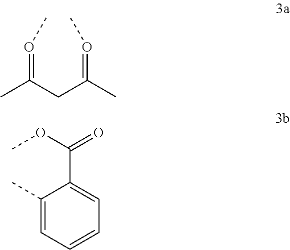
wherein, in Formulae 3a and 3b, a part shown in dotted lines indicates a binding with the iridium molecule.

8. The iridium complex as claimed in claim 1, wherein the compound of Formula 1 is one of Compounds 1 to 18:

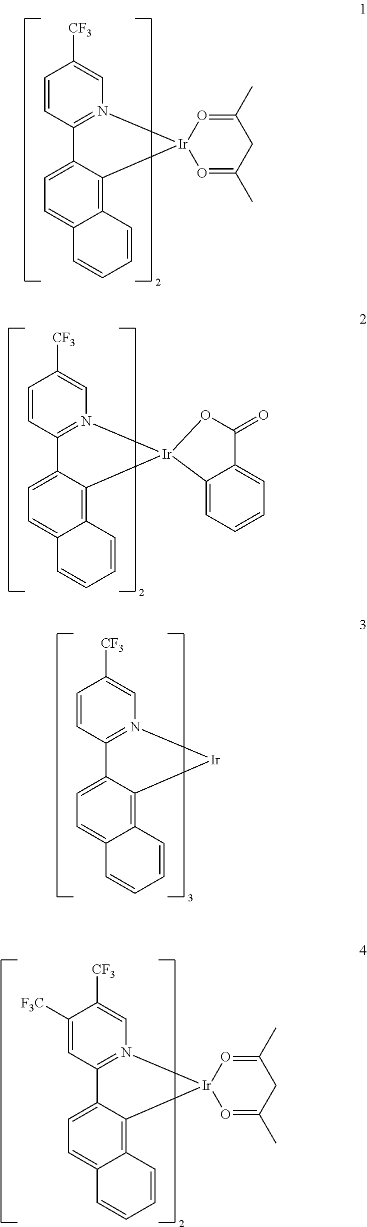

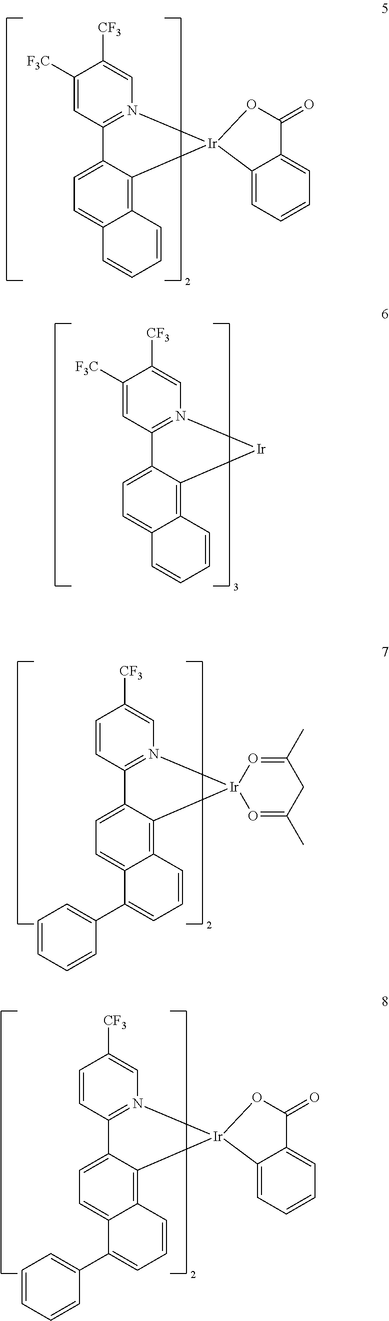

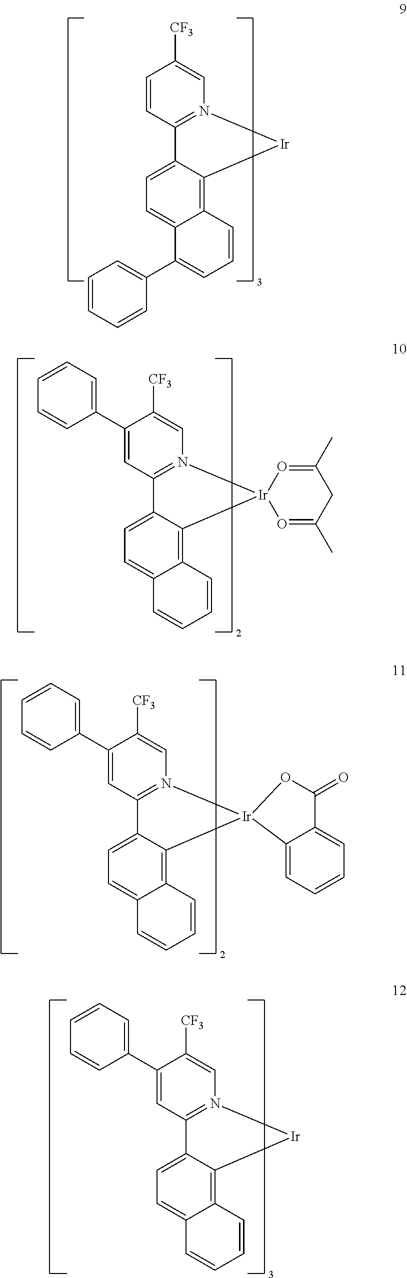

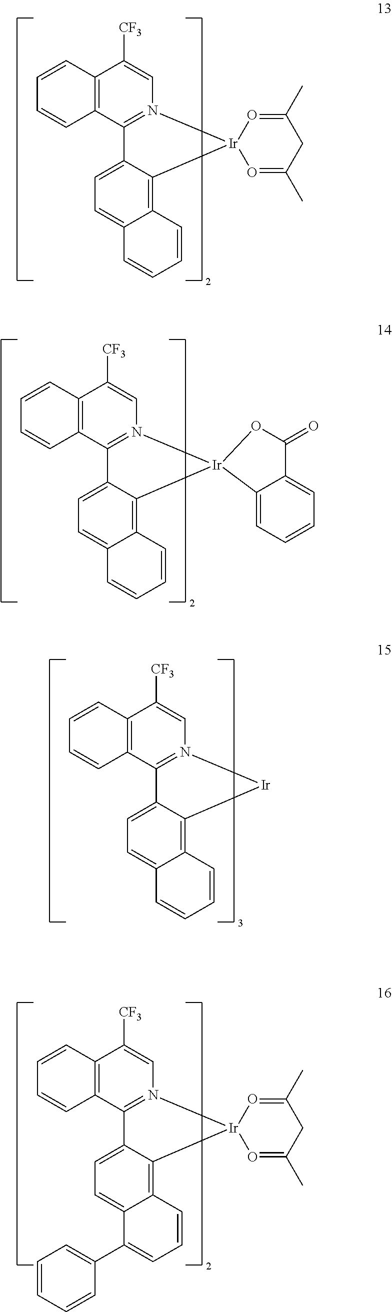

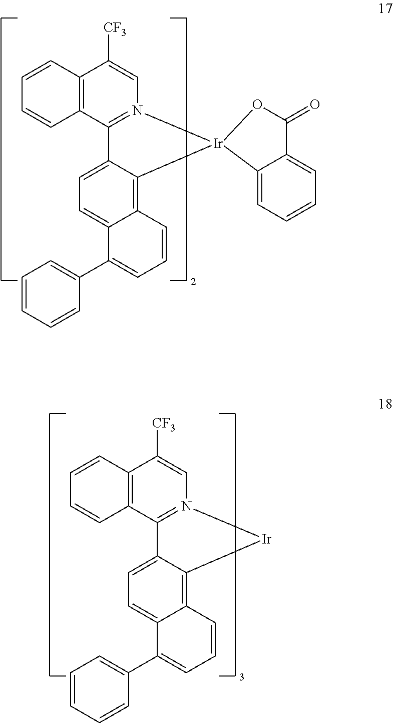

9. An organic light-emitting device, comprising:
a first electrode;
a second electrode; and
an organic layer disposed between the first electrode and the second electrode, wherein the organic layer includes the iridium complex as claimed in claim 1.

10. The organic light-emitting device as claimed in claim 9, wherein the organic layer is an emission layer.

11. The organic light-emitting device as claimed in claim 9, wherein the organic layer is a red phosphorescent emission layer, and the iridium complex is a phosphorescent dopant.

12. The organic light-emitting device as claimed in claim 9, wherein the organic layer includes an emission layer, and, optionally, one or more of a hole injection layer, a hole transport layer, a functional layer having both hole injection and hole transport capabilities at the same time, an electron injection layer, an electron transport layer, or a functional layer having both electron injection and electron transport capabilities at the same time,
wherein the emission layer includes the iridium complex of claim 1, and
wherein the emission layer further includes an anthracene-based compound, an arylamine-based compound, or a styryl-based compound.

13. The organic light-emitting device as claimed in claim 9, wherein the organic layer includes an emission layer, and, optionally, one or more of a hole injection layer, a hole transport layer, or a functional layer having both hole injection and hole transport capabilities at the same time,
wherein a red emission layer of the emission layer includes the iridium complex of claim 1, and
wherein the emission layer further includes at least one layer selected from a green emission layer, a blue emission layer, and a white emission layer of the emission layer that includes a phosphorescent compound.

14. The organic light-emitting device as claimed in claim 13, wherein the hole injection layer, the hole transport layer, or the functional layer having both hole injection and hole transport capabilities at the same time includes a charge-generating material.

15. The organic light-emitting device as claimed in claim 14, wherein the charge-generating material is a p-dopant.

16. The organic light-emitting device as claimed in claim 15, wherein the p-dopant is a quinone derivative, a metal oxide, or a cyano group-containing compound.

17. The organic light-emitting device as claimed in claim 9, wherein the organic layer includes an emission layer, and, optionally, one or more of an electron injection layer, an electron transport layer, or a functional layer having both electron injection and electron transport capabilities at the same time,
wherein the emission layer includes the iridium complex of claim 1, and
wherein the electron injection layer, the electron transport layer, or the functional layer having both electron injection and electron transport capabilities at the same time includes an electron-transporting organic compound and a metal complex.

18. The organic light-emitting device as claimed in claim 17, wherein the metal complex is lithium quinolate (LiQ) or Compound 203:

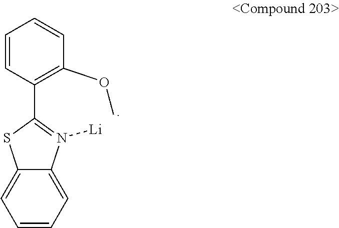

19. The organic light-emitting device as claimed in claim 9, wherein the organic layer is formed using a wet process.

20. A flat panel display device, comprising the organic light-emitting device of claim 9,
wherein the first electrode of the organic light-emitting device is electrically connected to a source electrode or a drain electrode of a thin film transistor (TFT).
